(19) United States
(12) Patent Application Publication
(10) Pub. No.: US 2025/0008726 A1
(43) Pub. Date: Jan. 2, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Kang Lib KIM, Suwon-si (KR); Jaeduk LEE, Suwon-si (KR); Sea Hoon LEE, Suwon-si (KR); Tackhwi LEE, Suwon-si (KR); Seongpil CHANG, Suwon-si (KR)

(73) Assignee: Samsung Electronics Co., Ltd., Suwon-si (KR)

(21) Appl. No.: 18/514,801

(22) Filed: Nov. 20, 2023

(30) Foreign Application Priority Data
Jun. 27, 2023 (KR) 10-2023-0082972

(51) Int. Cl. H10B 41/27; H01L 23/48; H01L 25/065; H10B 41/10; H10B 41/35; H10B 43/10; H10B 43/27; H10B 43/35; H10B 80/00

(52) U.S. Cl. CPC H10B 41/27; H01L 23/481; H01L 25/0652; H01L 28/75; H10B 41/10; H10B 41/35; H10B 43/10; H10B 43/27; H10B 43/35; H10B 80/00; H01L 2225/06506

(57) ABSTRACT

A semiconductor device includes a first substrate; a wiring layer on the first substrate; a second substrate on the wiring layer and including a conductive material; a first horizontal conductive layer and a second horizontal conductive layer sequentially stacked on the second substrate and connected to the second substrate; a gate stacking structure including an interlayer insulating layer and a gate electrode alternately stacked on the second horizontal conductive layer; a channel structure passing through the gate stacking structure and connected to the second substrate; a first capacitor electrode on a same layer as the second substrate; a second capacitor electrode overlapping the first capacitor electrode; and a first dielectric layer between the first capacitor electrode and the second capacitor electrode, wherein the second capacitor electrode is on a same layer as at least one of the wiring layer, the second substrate, the first horizontal conductive layer, or the gate electrode.

### CROSS-REFERENCE TO RELATED APPLICATION

This application claims priority to and the benefit of Korean Patent Application No. 10-2023-0082972 filed in the Korean Intellectual Property Office on Jun. 27, 2023, the entire contents of which are incorporated herein by reference.

### BACKGROUND

### 1. Field

The present disclosure relates to a semiconductor device and an electronic system including the same.

### 2. Description of the Related Art

A semiconductor is a material belonging to the intermediate region between a conductor and an insulator, and means a material that conducts electricity under predetermined conditions. Various semiconductor devices, such as memory devices and the like, may be manufactured using this semiconductor material. The memory devices may be classified into volatile memory devices and non-volatile memory devices. In the case of the non-volatile memory devices, contents may not be deleted when the power is turned off. Both volatile and non-volatile memory devices may be used in various electronic devices such as portable phones, digital cameras, and PCs.

It is desirable to increase the integration of the non-volatile memory devices according to the recent trend of increased storage capacity. The integration of memory devices disposed in two dimensions on a flat surface may be limited. Accordingly, vertical non-volatile memory devices disposed in three dimensions have been proposed.

### SUMMARY

The present disclosure attempts to provide a semiconductor device for simplifying a process and increasing integration, and an electronic system including the same.

An example embodiment of the present disclosure provides a semiconductor device including: a first substrate; a wiring layer on the first substrate; a second substrate on the wiring layer and including a conductive material; a first horizontal conductive layer and a second horizontal conductive layer sequentially stacked on the second substrate and connected to the second substrate; a gate stacking structure including an interlayer insulating layer and a gate electrode alternately stacked on the second horizontal conductive layer; a channel structure passing through the gate stacking structure and connected to the second substrate; a first capacitor electrode on a same layer as the second substrate; a second capacitor electrode overlapping the first capacitor electrode; and a first dielectric layer between the first capacitor electrode and the second capacitor electrode, wherein the second capacitor electrode is on a same layer as at least one of the wiring layer, the second substrate, the first horizontal conductive layer, or the gate electrode.

Another example embodiment of the present disclosure provides a semiconductor device including: a first substrate; a second substrate to face the first substrate and including a conductive material; a wiring layer between the first substrate and the second substrate; a gate stacking structure including an interlayer insulating layer and a gate electrode alternately stacked between the wiring layer and the second substrate; a channel structure passing through the gate stacking structure and connected to the second substrate; a first capacitor electrode on a same layer as the second substrate; a second capacitor electrode overlapping the first capacitor electrode; and a first dielectric layer between the first capacitor electrode and the second capacitor electrode, wherein the second capacitor electrode is same layer as at least one of the wiring layer, the second substrate, or the gate electrode.

Another example embodiment of the present disclosure provides an electronic system including: a main substrate; a semiconductor device on the main substrate; and a controller electrically connected to the semiconductor device on the main substrate, wherein the semiconductor device includes a first substrate, a wiring layer on the first substrate, a second substrate on the wiring layer and including a conductive material, a gate stacking structure including an interlayer insulating layer and a gate electrode alternately stacked on the second substrate, a channel structure passing through the gate stacking structure and connected to the second substrate, a first capacitor electrode on a same layer as the second substrate, a second capacitor electrode overlapping the first capacitor electrode, and a first dielectric layer between the first capacitor electrode and the second capacitor electrode, wherein the second capacitor electrode is on a same layer as at least one of the wiring layer, the second substrate, or the gate electrode.

In example embodiments where the second capacitor electrode is on a same later as the second substrate, a sum of a thickness of the first capacitor electrode and a thickness of the second capacitor electrode corresponds to a thickness of the second substrate. For example, the sum of the thickness of the first capacitor electrode and a thickness of the second capacitor electrode may be the same, substantially the same, or equal to a thickness of the second substrate.

According to the example embodiments, the semiconductor device and the electronic system including the same may simplify the manufacturing process and may increase the integration.

### BRIEF DESCRIPTION OF THE DRAWINGS

FIG. 1 shows a cross-sectional view of a semiconductor device according to an example embodiment.

FIG. 2A and FIG. 2B show cross-sectional views of various examples of a channel structure in a semiconductor device shown in FIG. 1.

FIG. 3 shows a cross-sectional view of an enlarged region of FIG. 1.

FIG. 4 shows a cross-sectional view of a region of a semiconductor device according to an example embodiment.

FIG. 5 shows a cross-sectional view of a region of a semiconductor device according to an example embodiment.

FIG. 6 shows a cross-sectional view of a region of a semiconductor device according to an example embodiment.

FIG. 7 shows a cross-sectional view of a semiconductor device according to an example embodiment.

FIG. 8 shows a cross-sectional view of a region of a semiconductor device according to an example embodiment.

FIG. 9 to FIG. 12 sequentially show processing cross-sectional views of part of a method for manufacturing a semiconductor device according to an example embodiment.

FIG. 13 shows a cross-sectional view of a region of a semiconductor device according to an example embodiment.

FIG. 14 shows a cross-sectional view of a region of a semiconductor device according to an example embodiment.

FIG. 15 to FIG. 19 sequentially show processing cross-sectional views of part of a method for manufacturing a semiconductor device according to an example embodiment.

FIG. 20 shows a cross-sectional view of a region of a semiconductor device according to an example embodiment.

FIG. 21 shows a cross-sectional view of a region of a semiconductor device according to an example embodiment.

FIG. 22 shows a cross-sectional view of a region of a semiconductor device according to an example embodiment.

FIG. 23 shows a cross-sectional view of a region of a semiconductor device according to an example embodiment.

FIG. 24 shows a top plan view of some constituent elements of a semiconductor device according to an example embodiment.

FIG. 25 shows a cross-sectional view of a region of a semiconductor device according to an example embodiment.

FIG. 26 to FIG. 30 sequentially show processing cross-sectional views of part of a method for manufacturing a semiconductor device according to an example embodiment.

FIG. 31 shows a cross-sectional view of a region of a semiconductor device according to an example embodiment.

FIG. 32 shows a cross-sectional view of a region of a semiconductor device according to an example embodiment.

FIG. 33 shows a cross-sectional view of a region of a semiconductor device according to an example embodiment.

FIG. 34 to FIG. 39 sequentially show processing cross-sectional views of part of a method for manufacturing a semiconductor device according to an example embodiment.

FIG. 40 shows a cross-sectional view of a region of a semiconductor device according to an example embodiment.

FIG. 41 shows an electronic system including a semiconductor device according to an example embodiment.

FIG. 42 shows a perspective view of an electronic system including a semiconductor device according to an example embodiment.

FIG. 43 and FIG. 44 show cross-sectional views of a semiconductor package according to an example embodiment.

### DETAILED DESCRIPTION

The present disclosure will be described more fully hereinafter with reference to the accompanying drawings, in which example embodiments are shown. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” describes a position relative to the object portion, and does not necessarily mean positioned “on” or “above” the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “on a plane” means viewing the object portion from the top, and the phrase “on a cross-section” means viewing a cross-section of which the object portion is perpendicularly cut from the side.

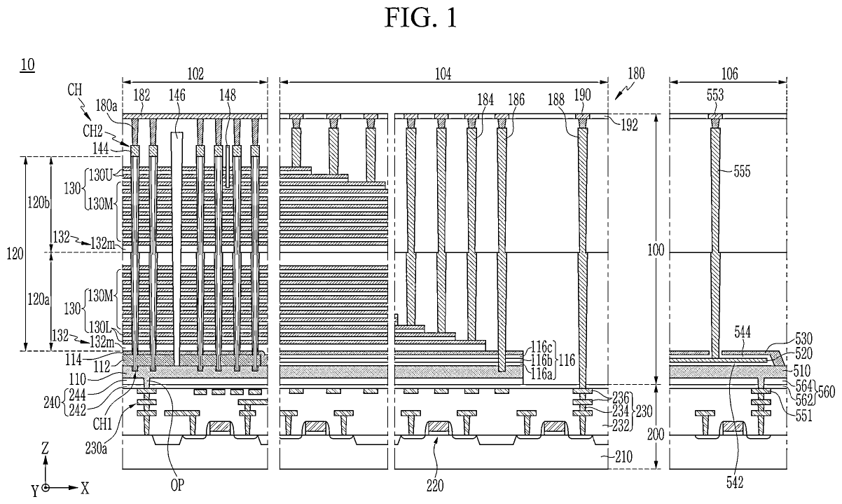

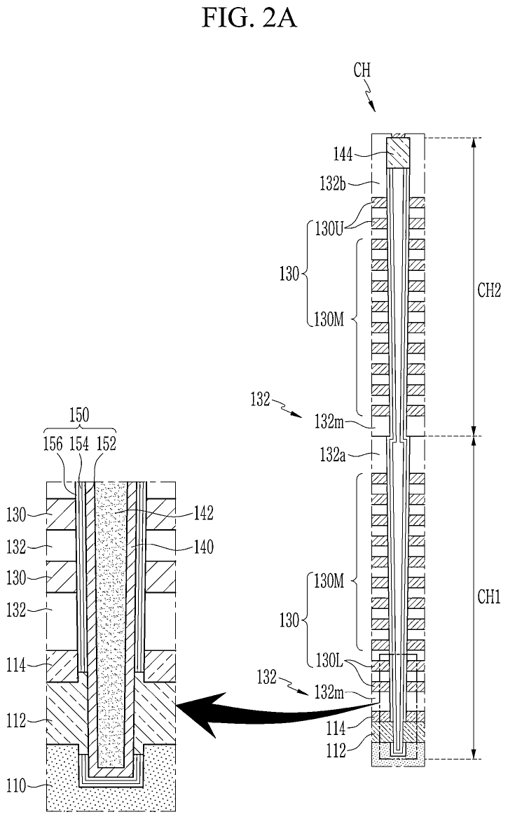

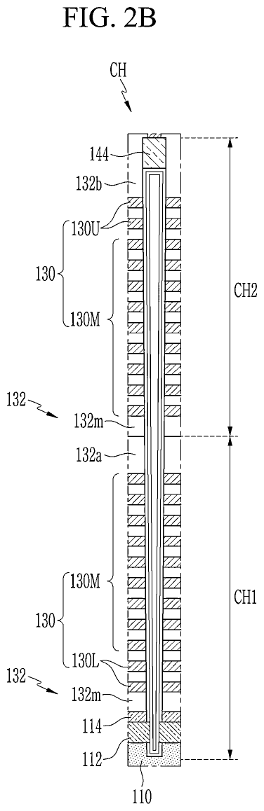

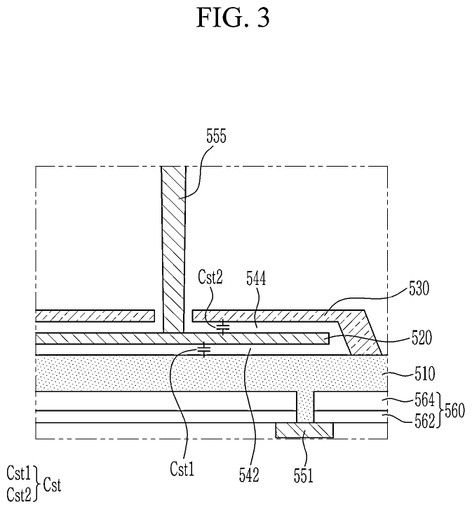

A semiconductor device according to an example embodiment will now be described with reference to FIG. 1, FIG. 2A, FIG. 2B, and FIG. 3.

FIG. 1 shows a cross-sectional view of a semiconductor device according to an example embodiment, and FIG. 2A and FIG. 2B show cross-sectional views of various example of a channel structure in a semiconductor device shown in FIG. 1. FIG. 3 shows a cross-sectional view of an enlarged region of FIG. 1. FIG. 3 shows an enlarged portion of a capacitor region of FIG. 1.

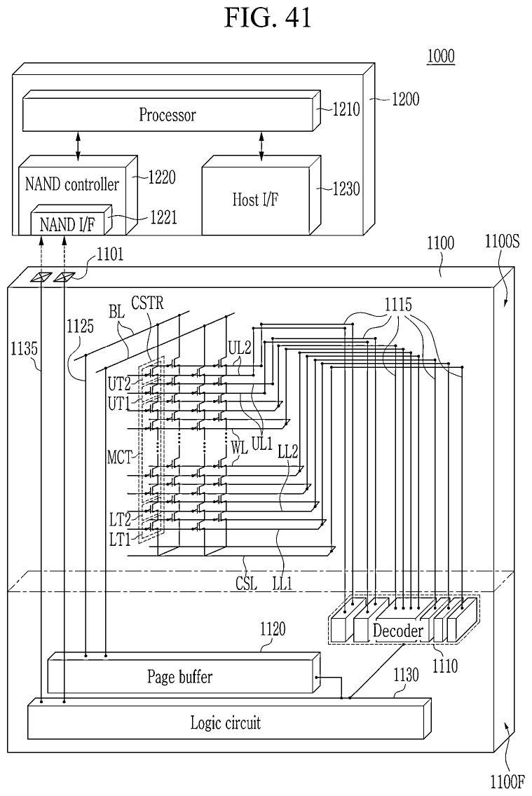

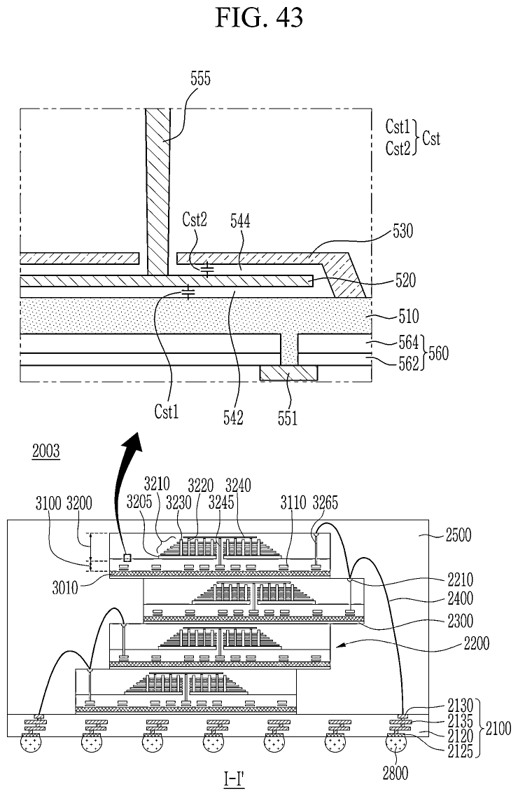

Referring to FIG. 1 and FIG. 2A, the semiconductor device 10 according to an example embodiment may include a cell region 100 in which a memory cell structure is installed, a circuit region 200 in which a peripheral circuit structure for controlling an operation of the memory cell structure is installed, and a capacitor region 106. For example, the circuit region 200 and the cell region 100 may correspond to a first structure 1100F and a second structure 1100S of the semiconductor device 1100 included in the electronic system 1000 shown in FIG. 41. In another way, the circuit region 200 and the cell region 100 may correspond to a first structure 3100 and a second structure 3200 of a semiconductor chip 2200 shown in FIG. 43. Referring to FIG. 41 and FIG. 43, a portion that corresponds to the capacitor region 106 is not shown, and a predetermined region of edges of first structures 1100F of FIG. 41 and 3100 of FIG. 43 and second structures 1100S of FIG. 41 and 3200 of FIG. 43 may correspond to the capacitor region 106.

Here, the circuit region 200 may include a peripheral circuit structure disposed on the first substrate 210, and the cell region 100 may include a gate stacking structure 120 and a channel structure CH disposed in the cell array region 102 of the second substrate 110 as a memory cell structure. A first wire portion 230 electrically connected to the peripheral circuit structure may be disposed in the circuit region 200, and a second wire portion 180 electrically connected to the memory cell structure may be disposed in the cell region 100.

In an example embodiment, the cell region 100 may be disposed in the circuit region 200. According to this, it is not necessary to secure an area corresponding to the circuit region 200 separately from the cell region 100 so the area of the semiconductor device 10 may be reduced. However, the example embodiment is not limited to this, and a circuit region 200 may be disposed next to the cell region 100. Other various changes are possible.

The circuit region 200 may include a first substrate 210, and a circuit element 220 and a first wire portion 230 disposed on the first substrate 210.

The first substrate 210 may be a semiconductor substrate including a semiconductor material. For example, the first substrate 210 may be a semiconductor substrate made of a semiconductor material, and may be a semiconductor substrate generated by forming a semiconductor layer on the base substrate. For example, the first substrate 210 may be made of silicon, epitaxial silicon, germanium, silicon-germanium, a silicon on insulator (SOI), or a germanium on insulator (GOI).

The circuit element 220 formed on the first substrate 210 may include various types of circuit elements for controlling an operation of the memory cell structure installed in the cell region 100. For example, the circuit element 220 may configure the peripheral circuit structure such as a decoder circuit 1110 of FIG. 41, a page buffer 1120 of FIG. 41, or a logic circuit 1130 of FIG. 41.

The circuit element 220 may, for example, include a transistor, and is not limited thereto. For example, the peripheral circuit element 220 may include active elements such as transistors and passive elements such as capacitors, resistors, or inductors. Some capacitors may be disposed in the circuit region 200, and other capacitors may be disposed in the capacitor region 106. The capacitor region 106 may be disposed near the circuit region 200 and the cell region 100. The capacitor disposed in the capacitor region 106 may be connected to the circuit element 220 disposed in the circuit region 200.

The first wire portion 230 disposed on the first substrate 210 may be electrically connected to the circuit element 220. In an example embodiment, the first wire portion 230 may include wiring layers 236 spaced with a first insulation layer 232 therebetween and connected to form a predetermined path by a contact via 234. The wiring layer 236 or the contact via 234 may include various types of conductive materials, and the first insulation layer 232 may include various types of insulating materials.

The cell region 100 may include a cell array region 102 and a connection region 104. A gate stacking structure 120 and a channel structure CH may be disposed on the second substrate 110 in the cell array region 102. A structure for connecting the gate stacking structure 120 and/or the channel structure CH disposed in the cell array region 102 to the circuit region 200 or external circuit may be disposed in the connection region 104.

In an example embodiment, the second substrate 110 may include a semiconductor material. For example, the second substrate 110 may include polysilicon to which impurities are doped. The second substrate 110 may function as a common source line. The second substrate 110 may function as a source region for supplying currents to the memory cells disposed on the second substrate 110. The second substrate 110 may have a plate shape. That is, the second substrate 110 may be made of a plate common source line.

An insulation layer 240 may be disposed between the second substrate 110 and the first wire portion 230. The insulation layer 240 may be a single layer or a multilayer. For example, the insulation layer 240 may include a lower insulation layer 242 and an upper insulation layer 244 disposed on the lower insulation layer 242. The insulation layer 240 may include various types of insulating materials. For example, the lower insulation layer 242 may include a silicon nitride, and the upper insulation layer 244 may include a silicon oxide.

The first wire portion 230 may further include a floating electrode 230a. In this instance, the floating electrode 230a may include layers disposed on a same layer as the wiring layers 236 and the contact via 234. However, it is not limited to this, and the floating electrode 230a may be disposed on the same layer as some of the wiring layers 236 and the contact via 234. The floating electrode 230a may include a conductive material. The floating electrode 230a may be connected to the second substrate 110. The insulation layer 240 disposed between the second substrate 110 and the first wire portion 230 may include an opening OP. That is, the opening OP passing through the insulation layer 240 may be formed. The opening OP may overlap the floating electrode 230a. The second substrate 110 may be connected to the floating electrode 230a through the opening OP formed in the insulation layer 240.

No additional signal is applied to the floating electrode 230a, and the floating electrode 230a may float. As the floating electrode 230a is electrically connected to the second substrate 110, plasma charges stored on the second substrate 110 may be removed in the process for manufacturing a semiconductor device 10 according to an example embodiment. For example, the floating electrode 230a may be connected to the first substrate 210, and the stored charges may be discharged to the first substrate 210 through the floating electrode 230a.

A gate stacking structure 120 including a cell insulation layer 132 and a gate electrode 130 alternately stacked on a first side (for example, a front side or an upper side) of the second substrate 110, and a channel structure CH passing through the gate stacking structure 120 and extending in a direction traversing the second substrate 110 may be formed in the cell array region 102.

Horizontal conductive layers 112 and 114 may be provided between the second substrate 110 and the gate stacking structure 120 in the cell array region 102. The horizontal conductive layers 112 and 114 may electrically connect a gap between the channel structure CH and the second substrate 110. For example, the horizontal conductive layers 112 and 114 may include a first horizontal conductive layer 112 disposed on the first side of the second substrate 110, and may further include a second horizontal conductive layer 114 disposed on the first horizontal conductive layer 112. That is, the first horizontal conductive layer 112 may be disposed between the second substrate 110 and the second horizontal conductive layer 114. The first horizontal conductive layer 112 may not be provided but the horizontal insulation layer 116 may be provided between the second substrate 110 and the gate stacking structure 120 in at least a predetermined region of the connection region 104. In the manufacturing process, a portion of the horizontal insulation layer 116 may be replaced with the first horizontal conductive layer 112, and another portion of the horizontal insulation layer 116 may remain in the connection region 104. The horizontal insulation layer 116 may be a single layer or a multilayer. For example, the horizontal insulation layer 116 may include a lower layer 116a, an intermediate layer 116b, and an upper layer 116c. In this instance, the intermediate layer 116b may be disposed between the lower layer 116a and the upper layer 116c. The horizontal insulation layer 116 may include various insulating materials. For example, the lower layer 116a and the upper layer 116c may include a silicon oxide, and the intermediate layer 116b may include a silicon nitride.

The first horizontal conductive layer 112 may function as part of the common source line of the semiconductor device 10. For example, the first horizontal conductive layer 112 may function as the common source line together with the second substrate 110. As shown in the enlarged drawing of FIG. 2A, the channel structure CH extends to pass through the horizontal conductive layers 112 and 114 and reach the second substrate 110, and a gate dielectric layer 150 is removed from a portion on which the first horizontal conductive layer 112 is disposed so the first horizontal conductive layer 112 may be directly connected to the channel layer 140 on a circumference of a channel layer 140. Accordingly, the first horizontal conductive layer 112 may electrically connect the second substrate 110 and the channel layer 140.

The first and second horizontal conductive layers 112 and 114 may include a semiconductor material (e.g., polysilicon). For example, the first horizontal conductive layer 112 may include polysilicon to which impurities are doped, and the second horizontal conductive layer 114 may include polysilicon to which impurities are doped or may include impurities diffused from the first horizontal conductive layer 112. However, the example embodiment is not limited to this, and the second horizontal conductive layer 114 may include an insulating material. Alternatively, the second horizontal conductive layer 114 may not be provided separately.

A gate stacking structure 120 on which the cell insulation layer 132 and the gate electrode 130 are alternately stacked may be disposed on the second substrate 110 (e.g., on the first and second horizontal conductive layers 112 and 114 formed on the second substrate 110).

In an example embodiment, the gate stacking structure 120 may include gate stacking structures 120a and 120b sequentially stacked on the second substrate 110. Then, the number of stacked gate electrodes 130 may be increased so the number of memory cells may be increased in a stable structure. For example, the gate stacking structure 120 may include the first and second gate stacking structures 120a and 120b and may simplify the structure while increasing the data storage capacity. However, the example embodiment is not limited to this, and the gate stacking structure 120 may be made of one gate stacking structure, and may include three or more gate stacking structures.

The gate electrode 130 may include a lower gate electrode 130L, a memory cell gate electrode 130M, and an upper gate electrode 130U sequentially disposed on the second substrate 110 in the gate stacking structure 120. The lower gate electrode 130L may be used as a gate electrode of a ground selecting transistor, the memory cell gate electrode 130M may configure a memory cell, and the upper gate electrode 130U may be used as a gate electrode of the string selecting transistor. The number of the memory cell gate electrodes 130M may be determined by data storage capacity of the semiconductor device 10. According to example embodiments, one or plural lower gate electrodes 130L and upper gate electrodes 130U may be installed, and may have the same or different structures as/from the memory cell gate electrode 130M. Part of the gate electrode 130, for example, the memory cell gate electrodes 130M disposed near the lower gate electrode 130L and the upper gate electrode 130U may be dummy gate electrodes.

The cell insulation layer 132 may include an interlayer insulating layer 132m disposed on a lower portion of the gate electrode 130 or between the two neighboring gate electrodes 130 in the first and second gate stacking structures 120a and 120b, and upper insulation layers 132a and 132b disposed on upper portions of the first and second gate stacking structures 120a and 120b. For example, the upper insulation layers 132a and 132b may include a first upper insulation layer 132a disposed on the upper portion of the first gate stacking structure 120a and a second upper insulation layer 132b disposed on the upper portion of the second gate stacking structure 120b. In this instance, the first upper insulation layer 132a is an intermediate insulation layer disposed between the first gate stacking structure 120a and the second gate stacking structure 120b, and the second upper insulation layer 132b is an uppermost insulation layer disposed on an uppermost portion of the gate stacking structure 120. The second upper insulation layer 132b may configure a portion or all of the cell region insulation layer disposed on the upper portion of the cell region 100. In an example embodiment, all of thicknesses of the cell insulation layers 132 may not be equal to each other. For example, the upper insulation layers 132a and 132b may be thicker than the interlayer insulating layer 132m. However, forms or structures of the cell insulation layer 132 are modifiable in many ways depending on example embodiments.

For a simple illustration, the drawing shows that the cell insulation layer 132 has a border between the first gate stacking structure 120a and the second gate stacking structure 120b in the connection region 104. However, the example embodiment is not limited to this. The insulation layers may have various types of stacking structures in the connection region 104, and the example embodiment is not limited thereto.

The gate electrode 130 may include various types of conductive materials. For example, the gate electrode 130 may include a metallic material such as tungsten (W), copper (Cu), or aluminum (Al). For another example, gate electrode 130 may include polysilicon, a metal nitride (e.g., a titanium nitride (TiN), tantalum nitride (TaN), etc.,), or combinations thereof. Although not shown, an insulation layer made of an insulating material may be disposed on an outside of the gate electrode 130, or part of the gate dielectric layer 150 may be disposed thereon. The cell insulation layer 132 may include various types of insulating materials. For example, the cell insulation layer 132 may include a silicon oxide, a silicon nitride, a silicon oxynitride, a low dielectric constant (low-k) material with a dielectric constant that is lower than that of the silicon oxide, or combinations thereof.

In an example embodiment, a channel structure CH extending in a direction (e.g., a vertical direction that is vertical to the second substrate 110) (a Z-axis direction in the drawing) passing through the gate stacking structure 120 and traversing the second substrate 110.

In further detail, the channel structure CH may include a channel layer 140, and a gate dielectric layer 150 disposed on the channel layer 140 between the gate electrode 130 and the channel layer 140. The channel structure CH may further include a core insulation layer 142 disposed inside the channel layer 140, and may further include a channel pad 144 disposed on the channel layer 140 and/or the gate dielectric layer 150.

The channel structures CH respectively form one memory cell string, and the channel structures CH may form rows and columns and may be spaced from each other in a plan view. For example, the channel structures CH may be disposed in various forms such as a lattice form or a zigzag form in a plan view. The channel structure CH may have a column shape. For example, the channel structure CH may have an inclined side so that its width becomes narrower as it approaches the second substrate 110 according to an aspect ratio in a cross-sectional view. However, the example embodiment is not limited to this, and the channel structure CH may have various dispositions, structures, and shapes.

A core insulation layer 142 may be provided in a central region of the channel structure CH, and a channel layer 140 may be formed while surrounding sidewalls of the core insulation layer 142. For example, the core insulation layer 142 may have a column shape (e.g., a cylindrical shape or a polygonal column shape), and the channel layer 140 may have a planar shape such as an annular shape. However, the example embodiment is not limited to this, and the core insulation layer 142 may not be provided and the channel layer 140 may have a column shape (e.g., a cylindrical shape or a polygonal column shape).

The channel layer 140 may include a semiconductor material, for example, polysilicon. The core insulation layer 142 may include various types of insulating materials. For example, the core insulation layer 142 may include a silicon oxide, a silicon nitride, a silicon oxynitride, or combinations thereof. However, materials of the channel layer 140 and the core insulation layer 142 are not limited thereto.

The gate dielectric layer 150 disposed between the gate electrode 130 and the channel layer 140 may include a tunneling layer 152, a charge storage layer 154, and a blocking layer 156 sequentially stacked on the channel layer 140.

In this instance, the tunneling layer 152 may allow charges to be tunneled according to a voltage applied to the gate electrode 130, and may include an insulating material for allowing the charges to be tunneled. The tunneling layer 152 may include a material such as a silicon oxide or a silicon oxynitride. For example, the tunneling layer 152 may be formed by stacking a layer including a silicon oxide and a layer including a silicon nitride.

The charge storage layer 154 disposed between the tunneling layer 152 and the blocking layer 156 may be used as a data storage region. For example, the charge storage layer 154 may include a silicon nitride for trapping the charges. When the charge storage layer 154 is made of a silicon nitride, it may have excellent retention and may be advantageous in integration, compared to the case when it is made of polysilicon. However, the material of the charge storage layer 154 is not limited thereto.

The blocking layer 156 may be disposed between the charge storage layer 154 and the gate electrode 130. The blocking layer 156 may include an insulating material for preventing an undesirable inflow of charges to the gate electrode 130. For example, the blocking layer 156 may include a silicon oxide, a silicon nitride, a silicon oxynitride, a high dielectric constant material, or combinations thereof.

Here, high dielectric constant material represents a dielectric material having a dielectric constant that is higher than that of the silicon oxide. For example, the high dielectric constant material may include an aluminum oxide (Al₂O₃), a tantalum oxide (Ta₂O₃), a titanium oxide (TiO₂), a yttrium oxide (Y₂O₃), a zirconium oxide (ZrO₂), a zirconium silicon oxide (ZrSiₓO_{y}), a hafnium oxide (HfO₂), a hafnium silicon oxide (HfSiₓO_{y}), a lanthanum oxide (La₂O₃), a lanthanum aluminum oxide (LaAlₓO_{y}), a lanthanum hafnium oxide (LaHfₓO_{y}), a hafnium aluminum oxide (HfAlₓO_{y}), a praseodymium oxide (Pr₂O₃), or combinations thereof.

The channel pad 144 may be disposed on the channel layer 140 and/or the gate dielectric layer 150. The channel pad 144 may be disposed to cover an upper side of the core insulation layer 142 and be electrically connected to the channel layer 140. The channel pad 144 is shown to cover an upper side of the gate dielectric layer 150, but is not limited thereto. For example, the channel pad 144 may not cover the upper side of the gate dielectric layer 150. In this instance, a lateral side of the channel pad 144 may be surrounded by the gate dielectric layer 150. The lateral side of the channel pad 144 may contact the tunneling layer 152. The channel pad 144 may include a conductive material, for example, impurity-doped polysilicon. However, the material of the channel pad 144 is not limited thereto, and it may be modifiable in many ways.

When the gate stacking structure 120 includes the stacked gate stacking structures 120a and 120b as described above, the channel structure CH may have channel structures CH1 and CH2 respectively passing through the gate stacking structures 120a and 120b. For example, when the gate stacking structure 120 includes the first gate stacking structure 120a and the second gate stacking structure 120b, the channel structures CH may include a first channel structure CH1 passing through the first gate stacking structure 120a and extending therefrom, and a second channel structure CH2 passing through the second gate stacking structure 120b and extending therefrom.

The first channel structure CH1 may be connected to the second channel structure CH2. The first channel structure CH1 and the second channel structure CH2 may each have an inclined lateral side such that the width becomes narrower as they approach the second substrate 110 according to an aspect ratio in a cross-sectional view. As shown in FIG. 2A, a bent portion may be provided at a portion where the first channel structure CH1 is connected to the second channel structure CH2 due to a difference in width. For another example, as shown in FIG. 2B, the first channel structure CH1 and the second channel structure CH2 may have inclined lateral sides continuously connected with no bent portion. However, the shapes of the first channel structure CH1 and the second channel structure CH2 are not limited thereto, and may be modifiable in many ways.

FIG. 1 illustrates that the gate dielectric layer 150, the channel layer 140, and the core insulation layer 142 of the first channel structure CH1 and the second channel structure CH2 extend with each other to form an integral structure. When forming a first penetration portion for the first channel structure CH1 and a second penetration portion for the second channel structure CH2, the gate dielectric layer 150, the channel layer 140, and the core insulation layer 142 are formed over the first and second penetration portions to form the above-described structure. However, the embodiment is not limited to this. For another example, the gate dielectric layers 150, the channel layers 140, and the core insulation layers 142 of the first channel structure CH1 and the second channel structure CH2 may be formed separately from each other and may be electrically connected to each other. For example, the gate dielectric layer 150, the channel layer 140, and the core insulation layer 142 may be formed in the first penetration portion when the first penetration portion for the first channel structure CH1 is formed, and the gate dielectric layer 150, the channel layer 140, and the core insulation layer 142 may be formed in the second penetration portion when the second penetration portion for the second channel structure CH2 is formed. Other various changes are possible.

In an example embodiment, the channel pad 144 may be provided on the channel structure CH (e.g., the second channel structure CH2) provided in the gate stacking structure 120 (e.g., the second gate stacking structure 120b) disposed on an upper portion from among the gate stacking structures 120. Differing from this, the channel pad 144 may be respectively provided on the first channel structure CH1 and the second channel structure CH2. In this case, the channel pad 144 of the first channel structure CH1 may be connected to the channel layer 140 of the second channel structure CH2.

In an example embodiment, the gate stacking structure 120 may extend in a direction (e.g., a vertical direction, a Z-axis direction in the drawing) crossing the second substrate 110 and may be partitioned into multiple partitions in a plan view by a separation structure 146 penetrating the gate stacking structure 120.

For example, the separation structure 146 may penetrate the gate electrode 130 and the cell insulation layer 132 and may extend to the second substrate 110. The separation structure 146 may be provided in plurality so that the same may extend in one direction (a Y-axis direction in the drawing) and may be spaced apart from each other at predetermined intervals in an intersection direction (an X-axis direction in the drawing) traversing the one direction in a plan view. Accordingly, in a plan view, the gate stacking structures 120 may respectively extend in one direction (the Y-axis direction in the drawing) and may be spaced apart from each other at predetermined intervals in the intersection direction (the X-axis direction in the drawing). The gate stacking structures 120 partitioned by the separation structure 146 may constitute one memory cell block. However, the example embodiment is not limited to this, and a range of the memory cell block is not limited thereto.

For example, the separation structure 146 may have an inclined lateral side that decreases in width toward the second substrate 110 when seen in a cross-sectional view because of a high aspect ratio. However, the example embodiment is not limited to this, and the lateral side of the separation structure 146 may be vertical to the second substrate 110. FIG. 1 illustrates that the separation structure 146 has a continuous inclined lateral side in the first gate stacking structure 120a and the second gate stacking structure 120b and does not have a bent portion in a cross-sectional view. However, the example embodiment is not limited to this, and the separation structure 146 may have a bent portion at a boundary between the first gate stacking structure 120a and the second gate stacking structure 120b.

The separation structure 146 may be filled with various types of insulating materials. For example, the separation structure 146 may include an insulating material such as a silicon oxide, a silicon nitride, or a silicon oxynitride. However, the example embodiment is not limited to this, and the structure, shape, and material of the separation structure 146 may be changeable in many ways.

An upper separation pattern 148 may be formed on an upper portion of the gate stacking structure 120. The upper separation pattern 148 may be provided in plurality so that they may extend in one direction (the Y-axis direction in the drawing) and may be spaced apart from each other at predetermined intervals in the intersection direction (the X-axis direction in the drawing) traversing the one direction.

The upper separation pattern 148 may be formed by passing through one or a plurality of gate electrodes 130 including the upper gate electrodes 130U disposed between the separation structures 146. The upper separation pattern 148 may, for example, separate the three gate electrodes 130 from each other in the intersection direction (the X-axis direction in the drawing). However, the number of the gate electrodes 130 separated by the upper separation pattern 148 is not limited thereto, and it may be modifiable in many ways. The upper separation pattern 148 may be filled with an insulating material. For example, the upper separation pattern 148 may include an insulating material such as a silicon oxide, a silicon nitride, or a silicon oxynitride. However, the example embodiment is not limited to this, and the structure, shape, and material of the upper separation pattern 148 may be modifiable in many ways.

To connect the gate stacking structure 120 and the channel structure CH provided in the cell array region 102 to the circuit region 200 or the external circuit, a connection region 104 and a second wire portion 180 may be provided.

Here, the second wire portion 180 may include members for electrically connecting the gate electrode 130, the channel structure CH, the horizontal conductive layers 112 and 114 and/or the second substrate 110 to the circuit region 200 or the external circuit. For example, the second wire portion 180 may include a bit line 182, a gate contact portion 184, a source contact portion 186, a penetration plug 188, contact vias 180a respectively connected to them, and a connecting wire 190 for connecting them.

The bit line 182 may be disposed on the cell insulation layer 132 of the gate stacking structure 120 formed in the cell array region 102. The bit line 182 may extend in the intersection direction (the X-axis direction in the drawing) traversing one direction in which the gate electrode 130 extends. The bit line 182 may be electrically connected to the channel structure CH, for example, the channel pad 144 through the contact via 180a, for example, a bit line contact via.

The connection region 104 may be disposed around the cell array region 102. A portion of the second wire portion 180 may be disposed in the connection region 104. A member for a connection with the gate electrode 130, the horizontal conductive layers 112 and 114 and/or the second substrate 110, and the circuit region 200 may be provided in the connection region 104. In addition, the connection region 104 may include a portion on which an input and output pad and an input and output connecting wire are formed.

In further detail, the gate electrodes 130 may extend in one direction (the Y-axis direction in the drawing) in the connection region 104, and extending lengths of the gate electrodes 130 may be sequentially reduced in the connection region 104 in accordance with a distance from the second substrate 110. For example, the gate electrodes 130 may be disposed in a stair shape in the connection region 104. In this case, the gate electrodes 130 may have a stair shape in one direction or plurality of directions. In the connection region 104, the gate contact portions 184 may pass through the cell insulation layer 132 and may be electrically connected to the respective gate electrodes 130 extending to the connection region 104.

In the connection region 104, the source contact portion 186 may penetrate the cell insulation layer 132 and may be electrically connected to the horizontal conductive layers 112 and 114 and/or the second substrate 110, and the penetration plug 188 may penetrate the gate stacking structure 120 or may be disposed outside the gate stacking structure 120 and may be electrically connected to the first wire portion 230 of the circuit region 200.

The connecting wire 190 may be disposed in the cell array region 102 and/or the connection region 104. The bit line 182, the gate contact portion 184, the source contact portion 186 and/or the penetration plug 188 may be electrically connected to the connecting wire 190. For example, the gate contact portion 184, the source contact portion 186 and/or the penetration plug 188 may be connected to the connecting wire 190 through the contact via 180a.

FIG. 1 shows that the connecting wire 190 is provided as a single layer disposed on the same plane as the bit line 182, and the second insulation layer 192 is disposed on a portion that is not the second wire portion 180. However, this is briefly shown for convenience. Therefore, the connecting wire 190 includes wire layers for electrical connection with the bit line 182, the gate contact portion 184, the source contact portion 186 and/or the penetration plug 188, and may further include contact vias.

As described above, the bit line 182, the gate electrode 130, the horizontal conductive layers 112 and 114 and/or the second substrate 110 connected to the channel structure CH may be electrically connected to the circuit element 220 of the circuit region 200 by the second wire portion 180 and the first wire portion 230.

Referring to FIG. 1, in a cross-sectional view, the gate contact portion 184, the source contact portion 186 and/or the penetration plug 188 have an inclined lateral side so that their widths become narrower as they approach the second substrate 110 according to the aspect ratio, and a bent portion is provided at the boundary between the first gate stacking structure 120a and the second gate stacking structure 120b. However, the example embodiment is not limited to this. For example, it is possible for the gate contact portion 184, the source contact portion 186 and/or the penetration plug 188 to have no bent portion at the boundary between the first gate stacking structure 120a and the second gate stacking structure 120b. Other various changes are possible.

FIG. 1 illustrates that the gate contact portion 184 passes through the cell insulation layer 132, reaches the gate electrode 130, and is connected to the gate electrode 130 in the connection region 104. However, it is not limited to this, and the gate contact portion 184 may pass through the cell insulation layer 132 and the gate electrode 130 and may extend to the first wire portion 230 provided in the circuit region 200. In this instance, the gate contact portion 184 includes a pad corresponding to the gate electrode 130 to be connected from among the gate electrodes 130 included in the gate stacking structure 120, and may be insulated from other gate electrodes 130 by an insulating material.

A Cst disposed in the capacitor region 106 will now be described.

As shown in FIG. 1 and FIG. 3, the capacitor Cst disposed in the capacitor region 106 may include a first capacitor Cst1 and a second capacitor Cst2. The semiconductor device further includes a first capacitor electrode 510 and a second capacitor electrode 520 disposed in the capacitor region 106. The first capacitor electrode 510 may overlap the second capacitor electrode 520 to configure the first capacitor Cst1. The semiconductor device may further include a third capacitor electrode 530 disposed in the capacitor region 106. The second capacitor electrode 520 may overlap the third capacitor electrode 530 to configure the second capacitor Cst2.

The first capacitor electrode 510 may be disposed on the same layer as the second substrate 110. The first capacitor electrode 510 may include the same material as the second substrate 110, and may be formed in the same process. For example, the first capacitor electrode 510 may include polysilicon to which impurities are doped. The first capacitor electrode 510 may have substantially the same thickness as the second substrate 110. The first capacitor electrode 510 may not be connected to the second substrate 110. That is, the first capacitor electrode 510 may be separated from the second substrate 110. Different voltages may be applied to the first capacitor electrode 510 and the second substrate 110.

The semiconductor device may further include a first voltage line 551 disposed in the capacitor region 106. The first voltage line 551 may be disposed on the same layer as the first wire portion 230. For example, the first voltage line 551 may be disposed on the same layer as the wiring layers 236 and the floating electrode 230a. The first voltage line 551 may include the same material as the wiring layer 236 and the floating electrode 230a, and may be formed in the same process. For example, the first voltage line 551 may include a conductive material. The first voltage line 551 may be electrically connected to a predetermined circuit element and may receive a predetermined first voltage. The first capacitor electrode 510 may be connected to the first voltage line 551. The first capacitor electrode 510 may receive the first voltage through the first voltage line 551. The first voltage may be a constant voltage.

An insulation layer 560 may be disposed between the first capacitor electrode 510 and the first voltage line 551. The insulation layer 560 disposed between the first capacitor electrode 510 and the first voltage line 551 may be disposed on the same layer as the insulation layer 240 disposed between the second substrate 110 and the first wire portion 230. The insulation layer 560 disposed between the first capacitor electrode 510 and the first voltage line 551 may include the same material as the insulation layer 240 disposed between the second substrate 110 and the first wire portion 230, and may be formed in the same process. The insulation layer 560 may be a single layer or a multilayer. For example, the insulation layer 560 may include a lower insulation layer 562 and an upper insulation layer 564 disposed on the lower insulation layer 562. The insulation layer 560 may include various types of insulating materials. For example, the lower insulation layer 562 may include a silicon nitride, and the upper insulation layer 564 may include a silicon oxide.

An opening is formed in the insulation layer 560 disposed between the first capacitor electrode 510 and the first voltage line 551. The first capacitor electrode 510 may be connected to the first voltage line 551 through the opening.

The second capacitor electrode 520 may be disposed on the same layer as the first horizontal conductive layer 112. The second capacitor electrode 520 may be disposed on the same layer as part of the first horizontal conductive layer 112. The second capacitor electrode 520 may be thinner than the first horizontal conductive layer 112. The second capacitor electrode 520 may not be connected to the first horizontal conductive layer 112. That is, the second capacitor electrode 520 may be separated from the first horizontal conductive layer 112. Different voltages may be applied to the second capacitor electrode 520 and the first horizontal conductive layer 112. The second capacitor electrode 520 may be disposed on the same layer as the horizontal insulation layer 116. The second capacitor electrode 520 may be disposed on the same layer as part of the horizontal insulation layer 116. For example, the second capacitor electrode 520 may be disposed on the same layer as the intermediate layer 116b of the horizontal insulation layer 116. The thickness of the second capacitor electrode 520 may be substantially equivalent to the thickness of the intermediate layer 116b of the horizontal insulation layer 116. The second capacitor electrode 520 may include a conductive material. For example, the second capacitor electrode 520 may include polysilicon to which impurities are doped, and tungsten.

The semiconductor device may further include a first dielectric layer 542 disposed between the first capacitor electrode 510 and the second capacitor electrode 520. The first dielectric layer 542 may be disposed on the same layer as the first horizontal conductive layer 112. The first dielectric layer 542 may be disposed on the same layer as another portion of the first horizontal conductive layer 112. The first dielectric layer 542 may be thinner than the first horizontal conductive layer 112. Further, the first dielectric layer 542 may be disposed on the same layer as the horizontal insulation layer 116. The first dielectric layer 542 may be disposed on the same layer as another portion of the horizontal insulation layer 116. For example, the first dielectric layer 542 may be disposed on the same layer as the lower layer 116a of the horizontal insulation layer 116. The thickness of the first dielectric layer 542 may be substantially equivalent to the thickness of the lower layer 116a of the horizontal insulation layer 116. The first dielectric layer 542 may include an insulating material. For example, the first dielectric layer 542 may include a silicon oxide.

The semiconductor device may further include a second voltage line 553 disposed in the capacitor region 106. The second voltage line 553 may be disposed on the same layer as the second wire portion 180. The second voltage line 553 may include the same material as the second wire portion 180 and may be formed in the same process. For example, the second voltage line 553 may include a conductive material. The second voltage line 553 may be electrically connected to a predetermined circuit element and may receive a predetermined second voltage. The second capacitor electrode 520 may be connected to the second voltage line 553. The second capacitor electrode 520 may receive a second voltage through the second voltage line 553. The second voltage may be a constant voltage.

The semiconductor device may further include a connection structure 555 for connecting the second capacitor electrode 520 and the second voltage line 553. The connection structure 555 may extend in the same direction (Z-axis direction in the drawing) as the channel structure CH. The connection structure 555 may also extend in the same direction as the gate contact portion 184, the source contact portion 186, and the penetration plug 188. The connection structure 555 may include a conductive material. For example, the connection structure 555 may include tungsten. The second capacitor electrode 520 may be connected to the second voltage line 553 through the connection structure 555.

The third capacitor electrode 530 may be disposed on the same layer as the second horizontal conductive layer 114. The third capacitor electrode 530 may include the same material as the second horizontal conductive layer 114, and may be formed in the same process. For example, the third capacitor electrode 530 may include polysilicon to which impurities are doped. The third capacitor electrode 530 may have a thickness that is substantially equivalent to the second horizontal conductive layer 114. The third capacitor electrode 530 may not be connected to the second horizontal conductive layer 114. That is, the third capacitor electrode 530 may be separated from the second horizontal conductive layer 114. Different voltages may be applied to the third capacitor electrode 530 and the second horizontal conductive layer 114.

The third capacitor electrode 530 may be connected to the first capacitor electrode 510. The third capacitor electrode 530 may be connected to the first voltage line 551 through the first capacitor electrode 510. The third capacitor electrode 530 may receive a first voltage through the first capacitor electrode 510 and the first voltage line 551.

The third capacitor electrode 530 may include an opening region. The connection structure 555 may be disposed in the opening region of the third capacitor electrode 530. Therefore, the connection structure 555 may not be connected to the third capacitor electrode 530.

The semiconductor device may further include a second dielectric layer 544 disposed between the second capacitor electrode 520 and the third capacitor electrode 530. The second dielectric layer 544 may be disposed on the same layer as the first horizontal conductive layer 112. The second dielectric layer 544 may be disposed on the same layer as the other portion of the first horizontal conductive layer 112. The second dielectric layer 544 may be thinner than the first horizontal conductive layer 112. The second dielectric layer 544 may also be disposed on the same layer as the horizontal insulation layer 116. The second dielectric layer 544 may be disposed on the same layer as the other portion of the horizontal insulation layer 116. For example, the second dielectric layer 544 may be disposed on the same layer as the upper layer 116c of the horizontal insulation layer 116. The thickness of the second dielectric layer 544 may be substantially equivalent to the thickness of the upper layer 116c of the horizontal insulation layer 116. The second dielectric layer 544 may include an insulating material. For example, the second dielectric layer 544 may include a silicon oxide.

The semiconductor device may include a first capacitor Cst1 configured with the first capacitor electrode 510 and the second capacitor electrode 520 overlapping each other with the first dielectric layer 542 therebetween. The semiconductor device may include a second capacitor Cst2 configured with the second capacitor electrode 520 and the third capacitor electrode 530 overlapping each other with the second dielectric layer 544 therebetween. The respective electrodes configuring the capacitor, the dielectric layers disposed among them, and the voltage lines connected to the electrodes may be disposed on the same layer as the constituent elements disposed in the circuit region 200 and the cell region 100. That is, the process may be simplified and the integration may be increased by forming the capacitor Cst in the capacitor region 106 by use of the constituent elements disposed in the circuit region 200 and the cell region 100.

The shapes and the dispositions of the above-described first capacitor electrode, the second capacitor electrode, and the third capacitor electrode, and the positions and the shapes of the wires for transmitting voltages to the electrodes are modifiable in many ways, some of which will now be described. However, they are not limited to this, and there may be numerous variations expected by a person of an ordinary skill in the art.

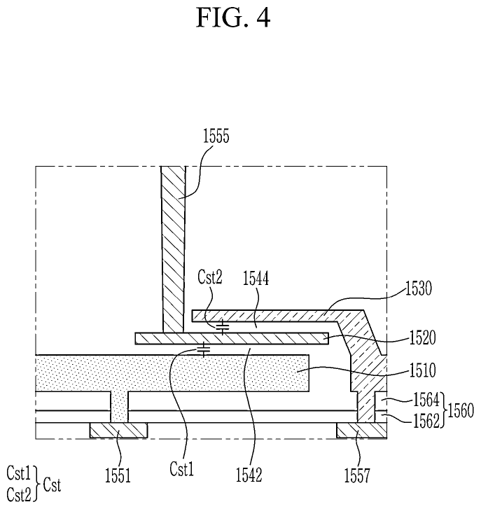

A semiconductor device according to an example embodiment will now be described with reference to FIG. 4.

FIG. 4 shows a cross-sectional view of a region of a semiconductor device according to an example embodiment. FIG. 4 shows a portion of a capacitor region of a semiconductor device according to an example embodiment.

The semiconductor device according to an example embodiment shown in FIG. 4 mostly corresponds to the semiconductor device according to an example embodiment shown in FIG. 1 to FIG. 3 so the description thereof will be omitted and the differences will be mainly described. In addition, the same or similar reference numerals are used for constituent elements that are identical or similar to those of the previous example embodiment. The present example embodiment is partially different from the previous example embodiment in that the third capacitor electrode is not directly connected to the first capacitor electrode, which will be described below.

The semiconductor device may include a cell region, a circuit region, and a capacitor region. As shown in FIG. 4, the semiconductor device may include a capacitor Cst disposed in the capacitor region. The capacitor Cst may include a first capacitor Cst1 and a second capacitor Cst2.

The semiconductor device includes a first capacitor electrode 1510 and a second capacitor electrode 1520 disposed in the capacitor region. The first capacitor electrode 1510 and the second capacitor electrode 1520 may overlap each other to configure the first capacitor Cst1. The semiconductor device may further include a third capacitor electrode 1530 disposed in the capacitor region. The second capacitor electrode 1520 and the third capacitor electrode 1530 may overlap each other to configure the second capacitor Cst2.

The semiconductor device may further include a first voltage line 1551 disposed in the capacitor region. The first capacitor electrode 1510 may be connected to the first voltage line 1551. The first capacitor electrode 1510 may receive the first voltage through the first voltage line 1551. An insulation layer 1560 may be disposed between the first capacitor electrode 1510 and the first voltage line 1551. The insulation layer 1560 may include a lower insulation layer 1562 and an upper insulation layer 1564. An opening may be formed in the insulation layer 1560, and the first capacitor electrode 1510 may be connected to the first voltage line 1551 through the opening.

The semiconductor device may further include a first dielectric layer 1542 disposed between the first capacitor electrode 1510 and the second capacitor electrode 1520. The first capacitor electrode 1510 and the second capacitor electrode 1520 overlap each other with the first dielectric layer 1542 therebetween to configure the first capacitor Cst1.

The semiconductor device may further include a connection structure 1555 connected to the second capacitor electrode 1520. The first connection structure 1555 may extend in the direction (Z-axis direction in the drawing) that is vertical to the first substrate. Although not shown, the connection structure 1555 may be connected to the second voltage line. The second capacitor electrode 1520 may be connected to the second voltage line through the connection structure 1555, and may receive the second voltage from the second voltage line.

The semiconductor device may further include a third voltage line 1557 disposed in the capacitor region. The third voltage line 1557 may be disposed on the same layer as the first voltage line 1551. The third voltage line 1557 may include the same material as the first voltage line 1551 and may be formed in the same process. The third voltage line 1557 may be electrically connected to a predetermined circuit element and may receive a predetermined third voltage. The third capacitor electrode 1530 may be connected to the third voltage line 1557. The third capacitor electrode 1530 may receive the third voltage through the third voltage line 1557. The third voltage may be a constant voltage. In this instance, the third voltage may be equal to/different from the first voltage. That is, the same voltage/different voltages may be applied to the first capacitor electrode 1510 and the third capacitor electrode 1530. The insulation layer 1560 may be disposed between the third capacitor electrode 1530 and the third voltage line 1557. An opening may be formed in the insulation layer 1560, and the third capacitor electrode 1530 may be connected to the third voltage line 1557 through the opening.

The semiconductor device may further include a second dielectric layer 1544 disposed between the second capacitor electrode 1520 and the third capacitor electrode 1530. The second capacitor electrode 1520 and the third capacitor electrode 1530 may overlap each other with the second dielectric layer 1544 therebetween to configure the second capacitor Cst2.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor Cst in the capacitor region by use of the constituent elements disposed in the circuit region and the cell region.

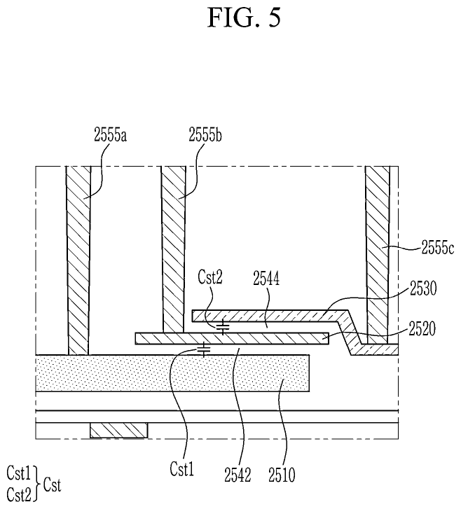

A semiconductor device according to an example embodiment will now be described with reference to FIG. 5.

FIG. 5 shows a cross-sectional view of a region of a semiconductor device according to an example embodiment. FIG. 5 shows a portion of a capacitor region of a semiconductor device according to an example embodiment.

The semiconductor device according to an example embodiment shown in FIG. 5 mostly corresponds to the semiconductor device according to an example embodiment shown in FIG. 1 to FIG. 3 so the description thereof will be omitted and the differences will be mainly described. In addition, the same or similar reference numerals are used for constituent elements that are identical or similar to those of the previous example embodiment. In the present example embodiment, it is partially different from the previous example embodiment in that it further includes structures respectively connected to the first capacitor electrode and the third capacitor electrode.

The semiconductor device may include a cell region, a circuit region, and a capacitor region. As shown in FIG. 5, the semiconductor device may include a capacitor Cst disposed in the capacitor region. The capacitor Cst may include a first capacitor Cst1 and a second capacitor Cst2.

The semiconductor device may include a first capacitor electrode 2510 and a second capacitor electrode 2520 disposed in the capacitor region, and a first dielectric layer 2542 disposed therebetween. The first capacitor electrode 2510 and the second capacitor electrode 2520 may overlap each other with the first dielectric layer 2542 therebetween to configure the first capacitor Cst1. The semiconductor device may further include a third capacitor electrode 2530 disposed in the capacitor region, and a second dielectric layer 2544 disposed between the second capacitor electrode 2520 and the third capacitor electrode 2530. The second capacitor electrode 2520 and the third capacitor electrode 2530 may overlap each other with the second dielectric layer 2544 therebetween to configure the second capacitor Cst2.

The semiconductor device may further include a first connection structure 2555a connected to the first capacitor electrode 2510. The first connection structure 2555a may extend in the direction (Z-axis direction in the drawing) that is vertical to the first substrate. Although not shown, the semiconductor device may further include a first voltage line for applying the first voltage, and the first connection structure 2555a may be connected to the first voltage line. The first capacitor electrode 2510 may be connected to the first voltage line through the first connection structure 2555a, and may receive the first voltage from the first voltage line.

The semiconductor device may further include a second connection structure 2555b connected to the second capacitor electrode 2520. The second connection structure 2555b may extend in the direction (Z-axis direction in the drawing) that is vertical to the first substrate. Although not shown, the semiconductor device may further include a second voltage line for applying the second voltage, and the second connection structure 2555b may be connected to the second voltage line. The second capacitor electrode 2520 may be connected to the second voltage line through the second connection structure 2555b, and may receive the second voltage from the second voltage line.

The semiconductor device may further include a third connection structure 2555c connected to the third capacitor electrode 2530. The third connection structure 2555c may extend in the direction (Z-axis direction in the drawing) that is vertical to the first substrate. Although not shown, the semiconductor device may further include a third voltage line for applying the third voltage, and the third connection structure 2555c may be connected to the third voltage line. The third capacitor electrode 2530 may be connected to the third voltage line through the third connection structure 2555c, and may receive the third voltage from the third voltage line.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor Cst in the capacitor region by use of the constituent elements disposed in the circuit region and the cell region.

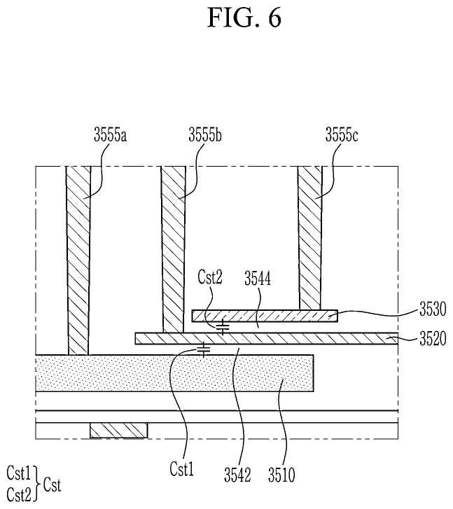

A semiconductor device according to an example embodiment will now be described with reference to FIG. 6

FIG. 6 shows a cross-sectional view of a region of a semiconductor device according to an example embodiment. FIG. 6 shows a portion of a capacitor region of a semiconductor device according to an example embodiment.

The semiconductor device according to an example embodiment shown in FIG. 6 mostly corresponds to the semiconductor device according to an example embodiment shown in FIG. 5 so the description thereof will be omitted and the differences will be mainly described. In addition, the same or similar reference numerals are used for constituent elements that are identical or similar to those of the previous example embodiment. In the present example embodiment, the positions and the shapes of the second capacitor electrode and the third capacitor electrode are partly different from the previous example embodiment, which will be described below.

The semiconductor device may include a cell region, a circuit region, and a capacitor region. as shown in FIG. 6, the semiconductor device may include a capacitor Cst disposed in the capacitor region. The capacitor Cst may include a first capacitor Cst1 and a second capacitor Cst2.

The semiconductor device includes a first capacitor electrode 3510 and a second capacitor electrode 3520 disposed in the capacitor region, and a first dielectric layer 3542 disposed therebetween. The first capacitor electrode 3510 and the second capacitor electrode 3520 may overlap each other with the first dielectric layer 3542 therebetween to configure the first capacitor Cst1. The first capacitor electrode 3510 may be connected to the first connection structure 3555a, and the second capacitor electrode 3520 may be connected to the second connection structure 3555b. The semiconductor device may further include a third capacitor electrode 3530 disposed in the capacitor region, and a second dielectric layer 3544 disposed between the second capacitor electrode 3520 and the third capacitor electrode 3530. The second capacitor electrode 3520 and the third capacitor electrode 3530 may overlap each other with the second dielectric layer 3544 therebetween to configure the second capacitor Cst2.

In the previous example embodiment, at least part of the third capacitor electrode 2530 may be disposed on a lower level than the second capacitor electrode 2520. In this instance, an insulation layer may be disposed between a side of the second capacitor electrode 2520 and the third capacitor electrode 2530. In the present example embodiment, the third capacitor electrode 3530 may be disposed on a higher level than the second capacitor electrode 3520. In this instance, the third capacitor electrode 3530 may face an upper side of the second capacitor electrode 3520 and may not face the side of the second capacitor electrode 3520.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor Cst in the capacitor region by use of the constituent elements disposed in the circuit region and the cell region.

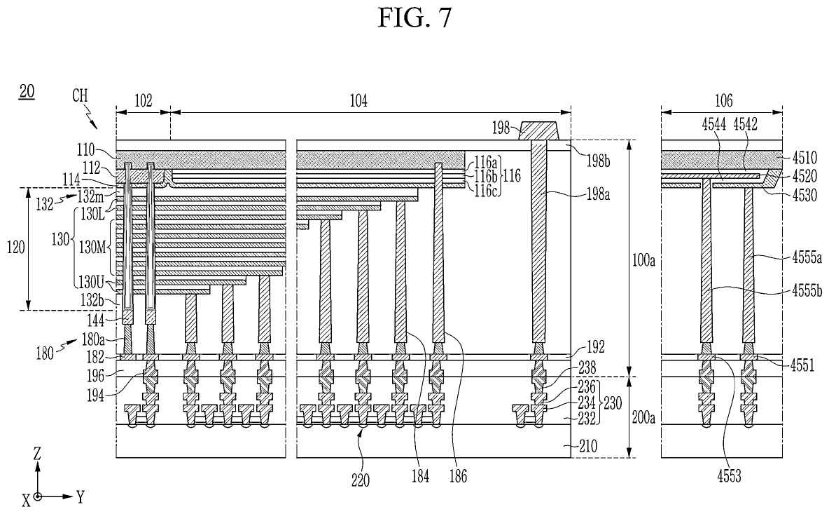

A semiconductor device according to an example embodiment will now be described with reference to FIG. 7.

FIG. 7 shows a cross-sectional view of a semiconductor device according to an example embodiment.

The example embodiment shown in FIG. 7 mostly corresponds to the example embodiment shown in FIG. 1 to FIG. 3 so the description thereof will be omitted and the differences will be mainly described. In addition, the same or similar reference numerals are used for constituent elements that are identical or similar to those of the previous example embodiment. The present example embodiment is partially different from the previous example embodiment in that the cell region is upside down, which will now be described

Referring to FIG. 7, the semiconductor device 20 may have a chip to chip (C2C) structure bonded by a wafer bonding method. That is, a lower chip including a circuit region 200a formed on the first substrate 210 is manufactured, an upper chip including a cell region 100a formed on the second substrate 110 is manufactured, and they may be bonded to manufacture the semiconductor device 20. The semiconductor device 20 may further include a capacitor region 106, and a portion of the capacitor region 106 may be included in the lower chip, and another portion of the capacitor region 106 may be included in the upper chip.

The circuit region 200a may have a first junction structure 238 on a side that faces the cell region 100a on the first substrate 210, the circuit element 220, and the first wire portion 230.

The cell region 100a may have a second junction structure 194 on a side that faces the circuit region 200a on the second substrate 110, the gate stacking structure 120, the channel structure CH, and the second wire portion 180.

The semiconductor device includes a first capacitor electrode 4510 and a second capacitor electrode 4520 disposed in the capacitor region 106, and a first dielectric layer 4542 disposed therebetween. The first capacitor electrode 4510 and the second capacitor electrode 4520 may overlap each other with the first dielectric layer 4542 therebetween to configure a first capacitor. The semiconductor device may further include a third capacitor electrode 4530 disposed in the capacitor region, and a second dielectric layer 4544 disposed between the second capacitor electrode 4520 and the third capacitor electrode 4530. The second capacitor electrode 1520 and the third capacitor electrode 1530 may overlap each other with the second dielectric layer 4544 therebetween to configure a second capacitor.

The semiconductor device may further include a first voltage line 4551 disposed in the capacitor region 106. The semiconductor device may further include a first connection structure 4555a connected to the first voltage line 4551. The first capacitor electrode 4510 may be connected to the third capacitor electrode 4530. The third capacitor electrode 4530 may be connected to the first voltage line 4551 through the first connection structure 4555a. The first capacitor electrode 4510 and the third capacitor electrode 4530 may receive the first voltage from the first voltage line 4551.

The semiconductor device may further include a second voltage line 4553 disposed in the capacitor region 106. The semiconductor device may further include a second connection structure 4555b connected to the second voltage line 4553. The second capacitor electrode 4520 may be connected to the second voltage line 4553 through the second connection structure 4555b. The second capacitor electrode 4520 may receive the second voltage from the second voltage line 4553.

Regarding the gate stacking structure 120, the gate electrode 130 may proceed to the circuit region 200a from the second substrate 110 and may include a lower gate electrode 130L, a memory cell gate electrode 130M, and an upper gate electrode 130U sequentially disposed on the second substrate 110. That is, as shown in FIG. 7, the gate stacking structure 120 may be sequentially stacked below the second substrate 110 so the gate stacking structure 120 shown in FIG. 1 to FIG. 2B may be disposed upside down.

Accordingly, the channel pad 144 and the second wire portion 180 disposed on the gate stacking structure 120 may be disposed near the circuit region 200a. A second junction structure 194 electrically connected to the second wire portion 180 may be provided on the side opposing the circuit region 200a. Other regions except the second junction structure 194 may be covered by the insulation layer 196. As described, the second wire portion 180 and second junction structure 194 may oppose the circuit region 200a in the cell region 100a.

For example, the second junction structure 194 of the cell region 100a and the first junction structure 238 of the circuit region 200a may be made of aluminum, copper, tungsten, or alloys thereof. For example, the first and second junction structures 238 and 194 may include copper so the cell region 100a and the circuit region 200a may be connected (e.g., may directly contact each other and may be bonded) by a copper-to-copper junction.

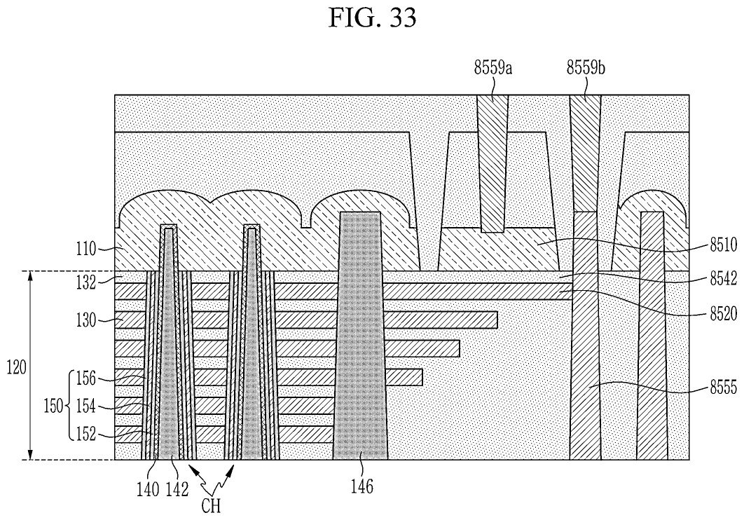

FIG. 7 shows that the gate stacking structure 120 is configured to be a single gate stacking structure, and as shown in FIG. 1, it may include gate stacking structures. Except what are individually described, descriptions on the configurations of the gate stacking structure 120 and the channel structure CH described with reference to FIG. 1 to FIG. 2B may be applied. FIG. 7 shows that an electrical connection configuration of the channel structure CH to the horizontal conductive layers 112 and 114 and/or the second substrate 110 corresponds to what is described with reference to FIG. 1. The example embodiment is not limited thereto, and the electrical connection configuration of the channel structure CH to the horizontal conductive layers 112 and 114 and/or the second substrate 110 may be modifiable in many ways. For example, in a like way of FIG. 33 to be described, the channel layer of the channel structure CH may protrude compared to the gate dielectric layer and may contact the second substrate 110.

The semiconductor device 20 may include an input/output pad 198 and an input/output connecting wire 198a electrically connected thereto. The input/output connecting wire 198a may be electrically connected to part of the second junction structure 194. The input/output pad 198 may, for example, be disposed on the insulation layer 198b for covering an external side of the second substrate 110. Depending on example embodiments, an additional input/output pad electrically connected to the circuit region 200a may be provided.

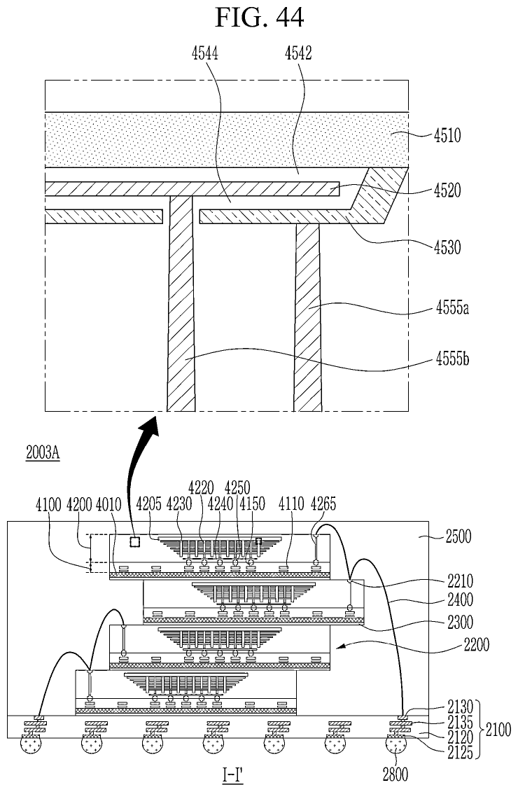

For example, the circuit region 200a and the cell region 100a may correspond to the first structure 1100F and the second structure 1100S of the semiconductor device 1100 included in the electronic system 1000 shown in FIG. 41. Alternatively, the circuit region 200a and the cell region 100a may correspond to the first structure 4100 and the second structure 4200 of the semiconductor chip 2200 shown in FIG. 44.

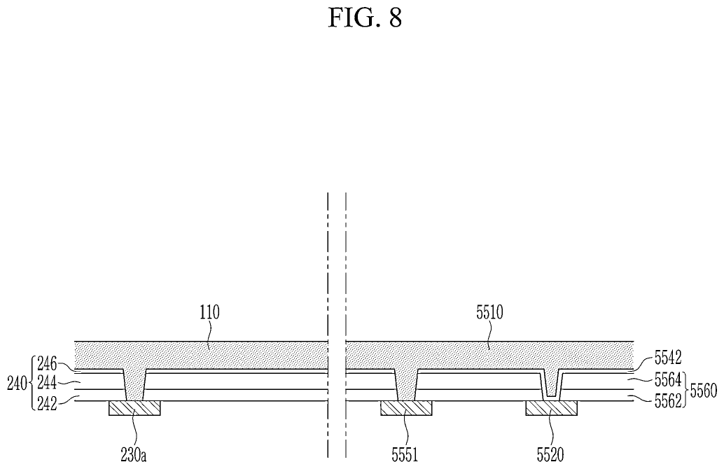

A semiconductor device according to an example embodiment will now be described with reference to FIG. 8.

FIG. 8 shows a cross-sectional view of a region of a semiconductor device according to an example embodiment. FIG. 8 shows a border between a circuit region and a cell region of a semiconductor device, and a portion of a capacitor region according to an example embodiment. Referring to FIG. 8, a left region may correspond to a border between a circuit region and a cell region, and a right region may correspond to a capacitor region.

The semiconductor device according to an example embodiment shown in FIG. 8 mostly corresponds to the semiconductor device according to an example embodiment shown in FIG. 1 to FIG. 3 so the description thereof will be omitted and the differences will be mainly described. In addition, the same or similar reference numerals are used for constituent elements that are identical or similar to those of the previous example embodiment. The present example embodiment is partially different from the previous example embodiment in that the second capacitor electrode may be disposed on the same layer as the first wire portion, which will be described below.

As shown in FIG. 8, the semiconductor device includes a second substrate 110 and a floating electrode 230a connected to the second substrate 110. An insulation layer 240 may be disposed between the second substrate 110 and the floating electrode 230a. The insulation layer 240 may include a lower insulation layer 242, an upper insulation layer 244, and a dummy insulation layer 246. An opening may be formed in the insulation layer 240, and the second substrate 110 may be connected to the floating electrode 230a through the opening.

The semiconductor device includes a first capacitor electrode 5510, a second capacitor electrode 5520, and a first dielectric layer 5542 disposed therebetween. The first capacitor electrode 5510 and the second capacitor electrode 5520 may overlap each other with the first dielectric layer 5542 therebetween to configure the capacitor. The first dielectric layer 5542 may be disposed on the same layer as the dummy insulation layer 246. The first dielectric layer 5542 may include the same material as the dummy insulation layer 246, and may be formed in the same process.

The first capacitor electrode 5510 may be disposed on the same layer as the second substrate 110. The first capacitor electrode 5510 may include the same material as the second substrate 110, and may be formed in the same process. The first capacitor electrode 5510 may have a thickness that is substantially equivalent to the second substrate 110. The first capacitor electrode 5510 may not be connected to the second substrate 110. That is, the first capacitor electrode 5510 may be separated from the second substrate 110. Different voltages may be applied to the first capacitor electrode 5510 and the second substrate 110.

The semiconductor device may further include a first voltage line 5551. The first voltage line 5551 may be disposed on the same layer as the first wire portion, for example, the floating electrode 230a. The first voltage line 5551 may include the same material as the floating electrode 230a, and may be formed in the same process. The first capacitor electrode 5510 may be connected to the first voltage line 5551. The first capacitor electrode 5510 may receive the first voltage through the first voltage line 5551.

An insulation layer 5560 and a first dielectric layer 5542 may be disposed between the first capacitor electrode 5510 and the first voltage line 5551. The insulation layer 5560 disposed between the first capacitor electrode 5510 and the first voltage line 5551 may be disposed on the same layer as at least a portion of the insulation layer 240 disposed between the second substrate 110 and the floating electrode 230a. The insulation layer 5560 may be a single layer or a multilayer. For example, the insulation layer 5560 may include a lower insulation layer 5562 and an upper insulation layer 5564. An opening is formed in the insulation layer 5560 and the first dielectric layer 5542, and the first capacitor electrode 5510 may be connected to the first voltage line 5551 through the opening.

The second capacitor electrode 5520 may be disposed on the same layer as the first wire portion, for example, the floating electrode 230a. The second capacitor electrode 5520 may include the same material as the floating electrode 230a, and may be formed in the same process. The insulation layer 5560 may include an opening overlapping the second capacitor electrode 5520, and the first dielectric layer 5542 and the first capacitor electrode 5510 may be disposed in the opening. The first capacitor electrode 5510 may overlap the second capacitor electrode 5520 with the first dielectric layer 5542 therebetween in the opening.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor in the capacitor region by use of the constituent elements disposed in the circuit region and the cell region.

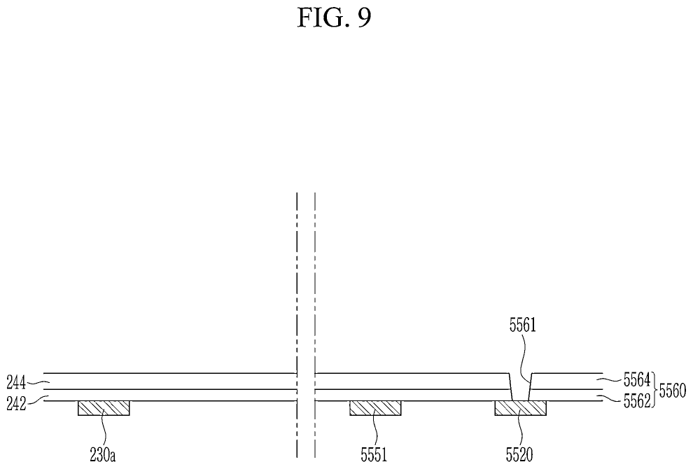

A method for manufacturing a semiconductor device according to an example embodiment will now be described with reference to FIG. 9 to FIG. 12.

FIG. 9 to FIG. 12 sequentially show processing cross-sectional views of part of a method for manufacturing a semiconductor device according to an example embodiment. FIG. 9 to FIG. 12 show a process for manufacturing a semiconductor device according to an example embodiment shown in FIG. 8.

As shown in FIG. 9, a floating electrode 230a, a first voltage line 5551, and a second capacitor electrode 5520 are formed by using a conductive material. For example, the floating electrode 230a, the first voltage line 5551, and the second capacitor electrode 5520 may be formed by depositing a conductive material and patterning the same. The floating electrode 230a, the first voltage line 5551, and the second capacitor electrode 5520 may be spaced from each other. Although not shown, various constituent elements included in the first wire portion as well as the floating electrode 230a may be formed together.

Lower insulation layers 242 and 5562 and upper insulation layers 244 and 5564 may be sequentially formed by using an insulating material on the floating electrode 230a, the first voltage line 5551, and the second capacitor electrode 5520. In this instance, the lower insulation layers 242 and 5562 may include a silicon nitride, and the upper insulation layers 244 and 5564 may include a silicon oxide. However, the materials of the lower insulation layers 242 and 5562 and the upper insulation layers 244 and 5564 are not limited thereto, and may be modifiable in many ways.

An opening 5561 is formed by patterning insulation layer 5560 covering the second capacitor electrode 5520. At least part of the upper side of the second capacitor electrode 5520 may be exposed by the opening 5561 formed in the insulation layer 5560.

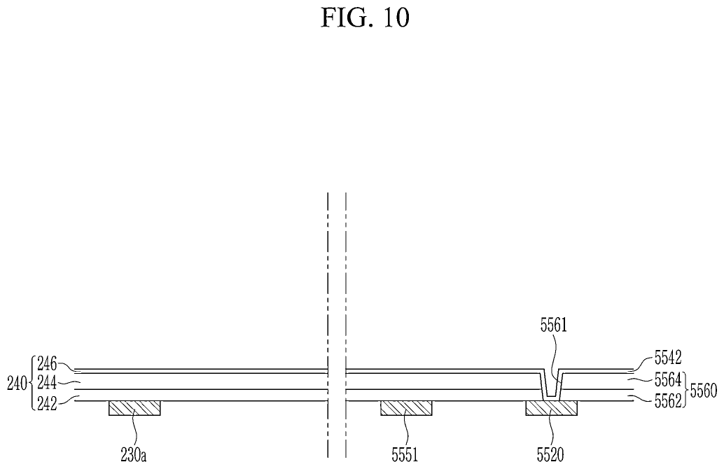

As shown in FIG. 10, a first dielectric layer 5542 is formed on the insulation layer 5560 in which the opening 5561 is formed by using an insulating material. For example, the first dielectric layer 5542 may be formed by depositing a silicon oxide. The first dielectric layer 5542 may be formed in the opening 5561 of the insulation layer 5560. The first dielectric layer 5542 may be disposed on the second capacitor electrode 5520 in the opening 5561. In this instance, the first dielectric layer 5542 may have a conformal shape in the opening 5561.

A dummy insulation layer 246 may be formed when the first dielectric layer 5542 is formed. The dummy insulation layer 246 may form the insulation layer 240 with the lower insulation layer 242 and the upper insulation layer 244. The dummy insulation layer 246 may include the same material as the first dielectric layer 5542, and may have a thickness that is substantially equivalent to the first dielectric layer 5542.

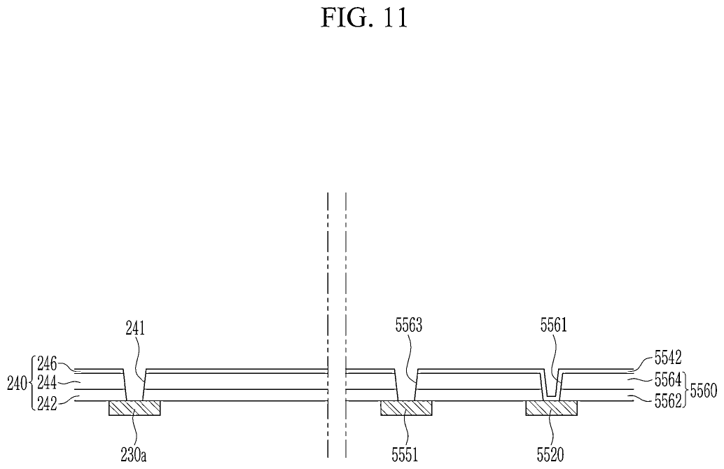

As shown in FIG. 11, openings 241 and 5563 are formed by patterning the insulation layers 240 and 5560 and the first dielectric layer 5542. At least part of the upper side of the floating electrode 230a may be exposed by the opening 241 formed in the insulation layer 240. At least part of the upper side of the first voltage line 5551 may be exposed by the opening 5563 formed in the insulation layer 5560.

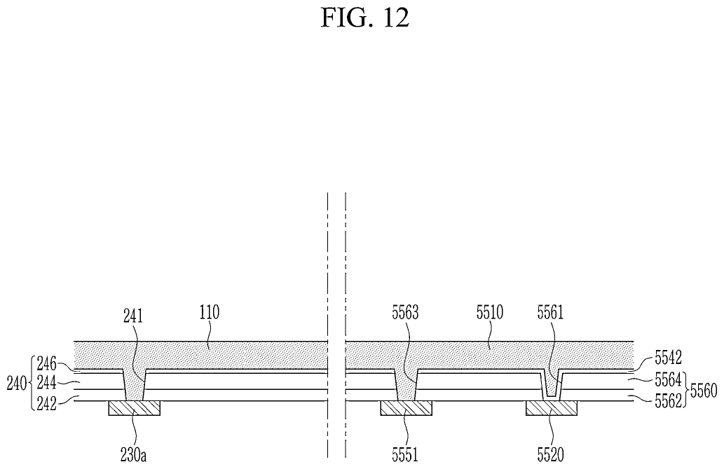

As shown in FIG. 12, a second substrate 110 and a first capacitor electrode 5510 are formed on the insulation layers 240 and 5560 and the first dielectric layer 5542 by using a conductive material. For example, the second substrate 110 and the first capacitor electrode 5510 may be formed by using polysilicon. In this instance, the second substrate 110 may fill the opening 241. The second substrate 110 may be connected to the floating electrode 230a through the opening 241. Further, the first capacitor electrode 5510 may fill the opening 5563. The first capacitor electrode 5510 may be connected to the first voltage line 5551 through the opening 5563.

The first capacitor electrode 5510 and the second capacitor electrode 5520 may overlap each other with the first dielectric layer 5542 therebetween in the opening 5561 to configure the capacitor.

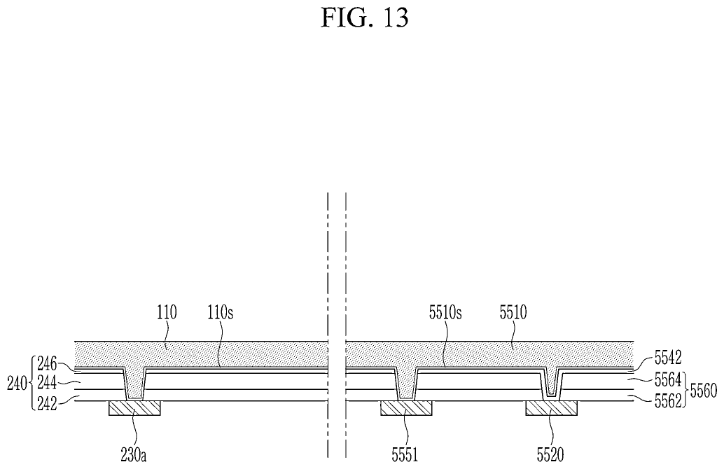

A semiconductor device according to an example embodiment will now be described with reference to FIG. 13.

FIG. 13 shows a cross-sectional view of a region of a semiconductor device according to an example embodiment.

The semiconductor device according to an example embodiment shown in FIG. 13 mostly corresponds to the semiconductor device according to an example embodiment shown in FIG. 8 so the description thereof will be omitted and the differences will be mainly described. In addition, the same or similar reference numerals are used for constituent elements that are identical or similar to those of the previous example embodiment. The present example embodiment is partially different from the previous example embodiment in that the barrier layer is disposed below the first capacitor electrode, which will be described below.

As shown in FIG. 13, the semiconductor device includes a first capacitor electrode 5510, a second capacitor electrode 5520, and a first dielectric layer 5542 disposed therebetween. A barrier layer 5510s may be further disposed below the first capacitor electrode 5510. The barrier layer 5510s may include a conductive material, for example, it may include a metal nitride. For example, the barrier layer 5510s may include a titanium nitride.

The first capacitor electrode 5510 may contact the first voltage line 5551 in the previous example embodiment, and the first capacitor electrode 5510 may contact the first voltage line 5551 in the present example embodiment. In the present example embodiment, a barrier layer 5510s may be disposed between the first capacitor electrode 5510 and the first voltage line 5551. The barrier layer 5510s may be disposed between the first capacitor electrode 5510 and the first dielectric layer 5542.

A dummy barrier layer 110s may be further disposed below the second substrate 110. The dummy barrier layer 110s may be disposed on the same layer as the barrier layer 5510s. The dummy barrier layer 110s may include the same material as the barrier layer 5510s, and may be formed in the same process. The dummy barrier layer 110s may be disposed between the second substrate 110 and the floating electrode 230a. The dummy barrier layer 110s may be disposed between the second substrate 110 and the insulation layer 240.

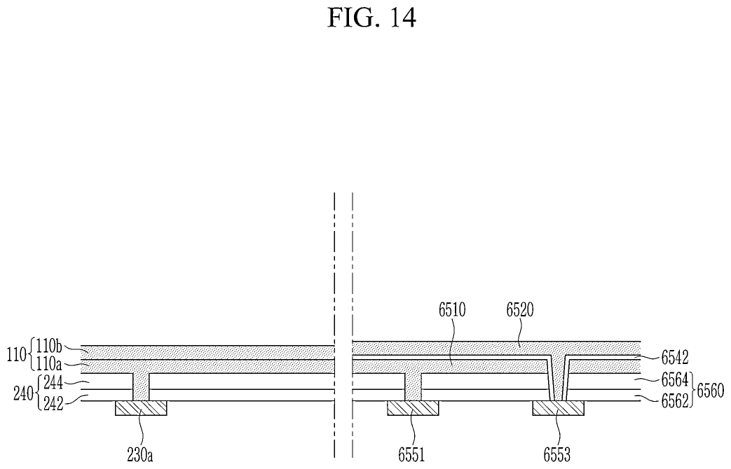

A semiconductor device according to an example embodiment will now be described with reference to FIG. 14.

FIG. 14 shows a cross-sectional view of a region of a semiconductor device according to an example embodiment.

The semiconductor device according to an example embodiment shown in FIG. 14 mostly corresponds to the semiconductor device according to an example embodiment shown in FIG. 1 to FIG. 3 so the description thereof will be omitted and the differences will be mainly described. In addition, the same or similar reference numerals are used for constituent elements that are identical or similar to those of the previous example embodiment. The present example embodiment is partially different from the previous example embodiment in that the second capacitor electrode may be disposed on the same layer as the second substrate, which will be described below.

As shown in FIG. 14, the semiconductor device includes a second substrate 110, and a floating electrode 230a connected to the second substrate 110. An insulation layer 240 may be disposed between the second substrate 110 and the floating electrode 230a. The insulation layer 240 may include a lower insulation layer 242 and an upper insulation layer 244. An opening may be formed in the insulation layer 240, and the second substrate 110 may be connected to the floating electrode 230a through the opening.

The second substrate 110 may include a sequentially stacked first layer 110a and a second layer 110b. The second layer 110b may be disposed on the first layer 110a. That is, a bottom surface of the second layer 110b may contact an upper side of the first layer 110a. The first layer 110a and the second layer 110b of the second substrate 110 may include a conductive material. The first layer 110a and the second layer 110b may include the same material, or may include different materials. The thickness of the first layer 110a may be substantially equivalent to the thickness of the second layer 110b. However, it is not limited to this, and the thickness of the first layer 110a may be different from the thickness of the second layer 110b.

The semiconductor device includes a first capacitor electrode 6510, a second capacitor electrode 6520, and a first dielectric layer 6542 disposed therebetween. The first capacitor electrode 6510 and the second capacitor electrode 6520 may overlap each other with the first dielectric layer 6542 therebetween to configure the capacitor.

The first capacitor electrode 6510 may be disposed on the same layer as the first layer 110a of the second substrate 110. The first capacitor electrode 6510 may include the same material as the first layer 110a of the second substrate 110, and may be formed in the same process. The first capacitor electrode 6510 may have a thickness that is substantially equivalent to the first layer 110a of the second substrate 110. The first capacitor electrode 6510 may not be connected to the first layer 110a of the second substrate 110. That is, the first capacitor electrode 6510 may be separated from the first layer 110a of the second substrate 110. Different voltages may be applied to the first capacitor electrode 6510 and the first layer 110a of the second substrate 110.

The semiconductor device may further include a first voltage line 6551. The first voltage line 6551 may be disposed on the same layer as the first wire portion, for example, the floating electrode 230a. The first voltage line 6551 may include the same material as the floating electrode 230a, and may be formed in the same process. The first capacitor electrode 6510 may be connected to the first voltage line 6551. The first capacitor electrode 6510 may receive the first voltage through the first voltage line 6551.

An insulation layer 6560 may be disposed between the first capacitor electrode 6510 and the first voltage line 6551. The insulation layer 6560 disposed between the first capacitor electrode 6510 and the first voltage line 6551 may be disposed on the same layer as the insulation layer 240 disposed between the second substrate 110 and the floating electrode 230a. The insulation layer 6560 may be a single layer or a multilayer. For example, the insulation layer 6560 may include a lower insulation layer 6562 and an upper insulation layer 6564. An opening is formed in the insulation layer 6560, and the first capacitor electrode 6510 may be connected to the first voltage line 6551 through the opening.

The second capacitor electrode 6520 may be disposed on the same layer as the second layer 110b of the second substrate 110. The second capacitor electrode 6520 may include the same material as the second layer 110b of the second substrate 110, and may be formed in the same process. The second capacitor electrode 6520 may have a thickness that is substantially equivalent to the second layer 110b of the second substrate 110. The second capacitor electrode 6520 may not be connected to the second layer 110b of the second substrate 110. That is, the second capacitor electrode 6520 may be separated from the second layer 110b of the second substrate 110. Different voltages may be applied to the second capacitor electrode 6520 and the second layer 110b of the second substrate 110. The thickness of the second capacitor electrode 6520 may be substantially equivalent to the thickness of the first capacitor electrode 6510. However, it is not limited to this, and the thickness of the second capacitor electrode 6520 may be different from the thickness of the first capacitor electrode 6510.

The semiconductor device may further include a second voltage line 6553. The second voltage line 6553 may be disposed on the same layer as the first wire portion, for example, the floating electrode 230a. The second voltage line 6553 may include the same material as the floating electrode 230a, and may be formed in the same process. The second voltage line 6553 may be disposed on the same layer as the first voltage line 6551. The second voltage line 6553 may include the same material as the first voltage line 6551, and may be formed in the same process. The second capacitor electrode 6520 may be connected to the second voltage line 6553. The second capacitor electrode 6520 may receive the second voltage through the second voltage line 6553.

An insulation layer 6560 and a first capacitor electrode 6510 may be disposed between the second capacitor electrode 6520 and the second voltage line 6553. Openings may be formed in the insulation layer 6560 and the first capacitor electrode 6510. Sidewalls of the openings of the insulation layer 6560 and the first capacitor electrode 6510 may be covered by the first dielectric layer 6542. An opening overlapping the second voltage line 6553 may be formed in the first dielectric layer 6542, and the second capacitor electrode 6520 may be connected to the second voltage line 6553 through the opening.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor in the capacitor region by use of the constituent elements disposed in the circuit region and the cell region.

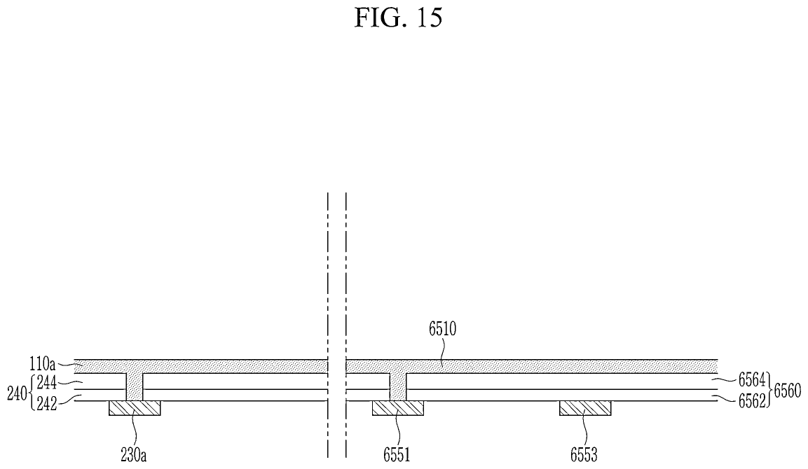

A method for manufacturing a semiconductor device according to an example embodiment will now be described with reference to FIG. 15 to FIG. 19.

FIG. 15 to FIG. 19 sequentially show processing cross-sectional views of part of a method for manufacturing a semiconductor device according to an example embodiment. FIG. 15 to FIG. 19 show a process for manufacturing a semiconductor device according to an example embodiment shown in FIG. 14.

As shown in FIG. 15, a floating electrode 230a, a first voltage line 6551, and a second voltage line 6553 are formed by using a conductive material. For example, a conductive material may be deposited and may then be patterned to form the floating electrode 230a, the first voltage line 6551, and the second voltage line 6553. The floating electrode 230a, the first voltage line 6551, and the second voltage line 6553 may be spaced from each other. Although not shown, various constituent elements included in the first wire portion as well as the floating electrode 230a may be formed together.

Lower insulation layers 242 and 6562 and upper insulation layers 244 and 6564 are formed on the floating electrode 230a, the first voltage line 6551, and the second voltage line 6553 by using an insulating material. In this instance, the lower insulation layers 242 and 6562 may include a silicon nitride, and the upper insulation layers 244 and 6564 may include a silicon oxide. However, the materials of the lower insulation layers 242 and 6562 and the upper insulation layers 244 and 6564 are not limited to this, and they are changeable with many other substances.

The insulation layers 240 and 6560 are patterned to form an opening for exposing at least part of the upper side of the floating electrode 230a, and form an opening for exposing at least part of the upper side of the first voltage line 6551.

A first layer 110a of the second substrate 110 and a first capacitor electrode 6510 are formed on the insulation layers 240 and 6560 by using a conductive material. The first layer 110a of the second substrate 110 may be connected to the floating electrode 230a through the opening formed in the insulation layer 240. The first capacitor electrode 6510 may be connected to the first voltage line 6551 through the opening formed in the insulation layer 6560.

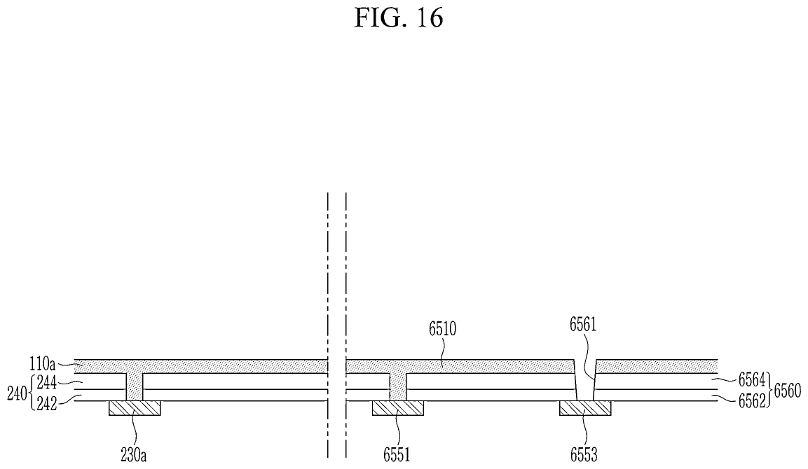

As shown in FIG. 16, an opening 6561 for exposing at least part of the upper side of the second voltage line 6553 by patterning the first capacitor electrode 6510 and the insulation layer 6560.

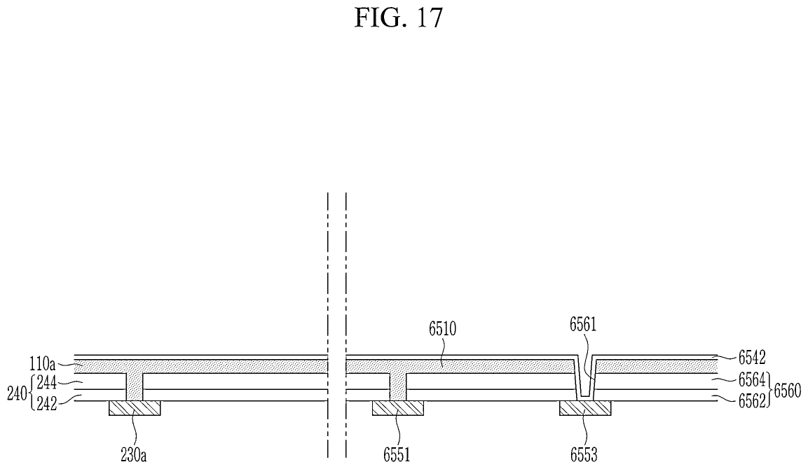

As shown in FIG. 17, a first dielectric layer 6542 is formed on the first capacitor electrode 6510 by using an insulating material. For example, the first dielectric layer 6542 may be formed by depositing a silicon oxide. The first dielectric layer 6542 may be formed in the opening 6561. The first dielectric layer 6542 may be disposed on the second voltage line 6553 in the opening 6561. The sidewall of the opening 6561 may be covered by the first dielectric layer 6542. The first dielectric layer 6542 may have a conformal shape in the opening 6561.

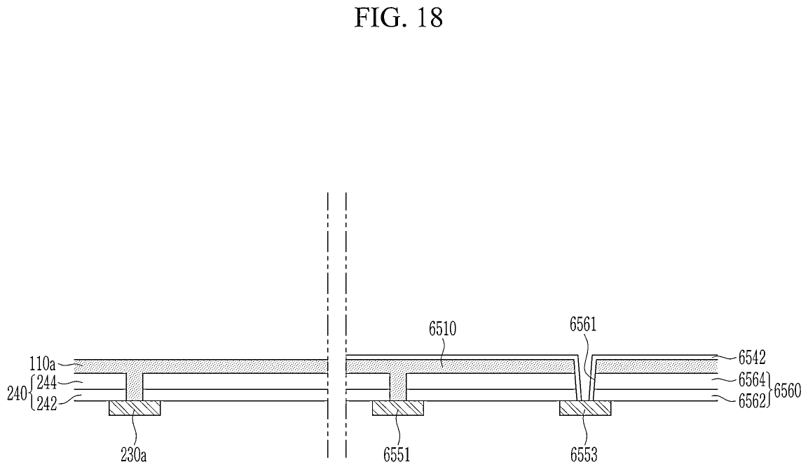

The first dielectric layer 6542 may be formed on the first layer 110a of the second substrate 110. As shown in FIG. 18, the first dielectric layer 6542 is patterned to remove a portion od the first dielectric layer 6542 disposed on the first layer 110a of the second substrate 110, and form an opening overlapping the second voltage line 6553. Hence, an upper side of the first layer 110a of the second substrate 110 may be exposed to the outside. At least part of the upper side of the second voltage line 6553 may be exposed to the outside. Sides of the insulation layer 6560 and the first capacitor electrode 6510 may be covered by the first dielectric layer 6542.

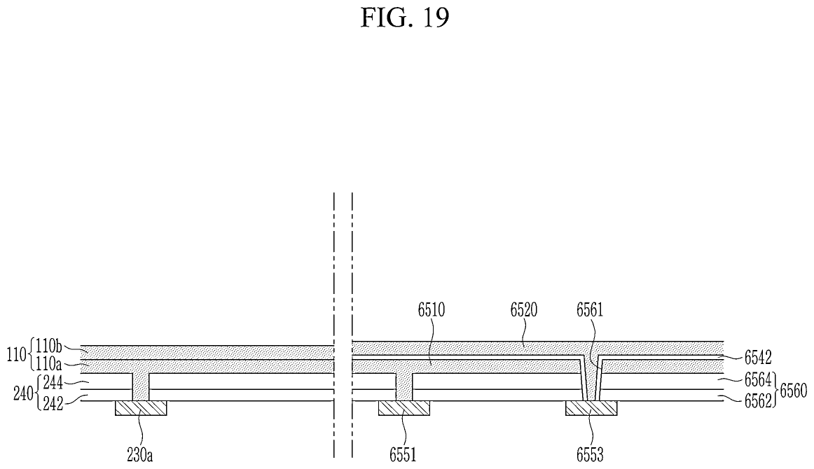

As shown in FIG. 19, the second layer 110b of the second substrate 110 and the second capacitor electrode 6520 are formed on the first layer 110a of the second substrate 110 and the first dielectric layer 6542 by using a conductive material. The second layer 110b of the second substrate 110 may be formed on the first layer 110a, and may contact the first layer 110a. The second capacitor electrode 6520 may be formed on the first dielectric layer 6542 and may overlap the first capacitor electrode 6510. The first capacitor electrode 6510 and the second capacitor electrode 6520 may overlap each other with the first dielectric layer 6542 therebetween to form the capacitor. Further, the second capacitor electrode 6520 may be connected to the second voltage line 6553 through the opening 6561 of the insulation layer 6560 and the opening of the first dielectric layer 6542.

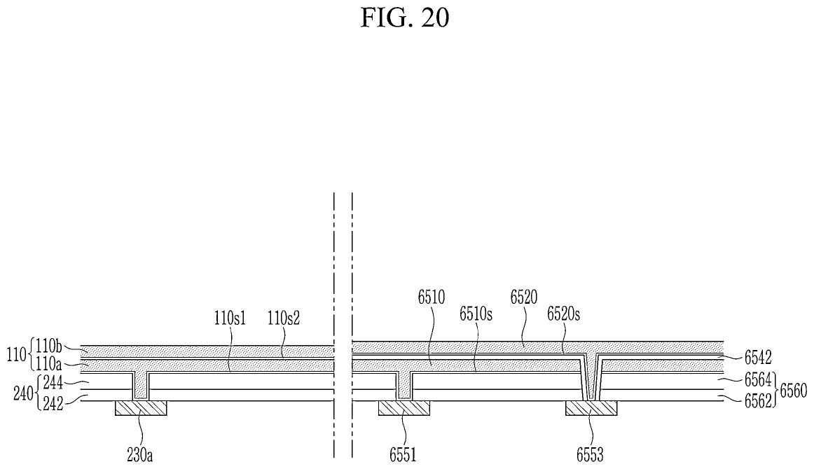

A semiconductor device according to an example embodiment will now be described with reference to FIG. 20.

FIG. 20 shows a cross-sectional view of a region of a semiconductor device according to an example embodiment.

The semiconductor device according to an example embodiment shown in FIG. 20 mostly corresponds to the semiconductor device according to an example embodiment shown in FIG. 14 so the description thereof will be omitted and the differences will be mainly described. In addition, the same or similar reference numerals are used for constituent elements that are identical or similar to those of the previous example embodiment. The present example embodiment is partially different from the previous example embodiment in that the barrier layer is disposed below the first capacitor electrode and the second capacitor electrode, which will be described below.

As shown in FIG. 20, the semiconductor device includes a first capacitor electrode 6510, a second capacitor electrode 6520, and a first dielectric layer 6542 disposed therebetween. A first barrier layer 6510s may be further disposed below the first capacitor electrode 6510. A second barrier layer 6520s may be further disposed below the second capacitor electrode 6520. The first barrier layer 6510s and the second barrier layer 6520s may include a conductive material, for example, it may include a metal nitride. For example, the first barrier layer 6510s and the second barrier layer 6520s may include a titanium nitride.

In the previous example embodiment, the first capacitor electrode 6510 may contact the first voltage line 6551, and the second capacitor electrode 6520 may contact the second voltage line 6553. In the present example embodiment, the first barrier layer 6510s may be disposed between the first capacitor electrode 6510 and the first voltage line 6551. The first barrier layer 6510s may be disposed between the first capacitor electrode 6510 and the insulation layer 6560. A second barrier layer 6520s may be disposed between the second capacitor electrode 6520 and the second voltage line 6553. The second barrier layer 6520s may be disposed between the second capacitor electrode 6520 and the first dielectric layer 6542.

A first dummy barrier layer 110s1 may be further disposed below the first layer 110a of the second substrate 110. The first dummy barrier layer 110s1 may be disposed on the same layer as the first barrier layer 6510s. The first dummy barrier layer 110s1 may include the same material as the first barrier layer 6510s, and may be formed in the same process. The first dummy barrier layer 110s1 may be disposed between the first layer 110a of the second substrate 110 and the floating electrode 230a. Further, the first dummy barrier layer 110s1 may be disposed between the second substrate 110 and the insulation layer 240. Depending on cases, the first dummy barrier layer 110s1 may be omitted.

A second dummy barrier layer 110s2 may be further disposed below the second layer 110b of the second substrate 110. The second dummy barrier layer 110s2 may be disposed on the same layer as the second barrier layer 6520s. The second dummy barrier layer 110s2 may include the same material as the second barrier layer 6520s, and may be formed in the same process. The second dummy barrier layer 110s2 may be disposed between the first layer 110a and the second layer 110b of the second substrate 110. Depending on cases, the second dummy barrier layer 110s2 may be omitted.

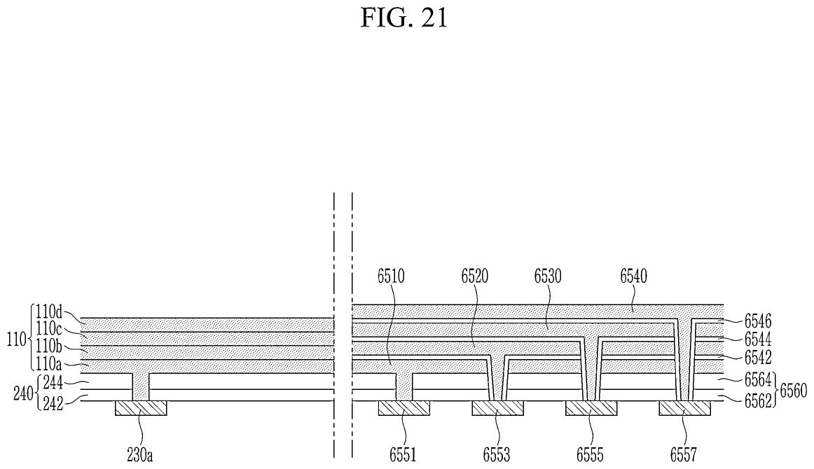

A semiconductor device according to an example embodiment will now be described with reference to FIG. 21.

FIG. 21 shows a cross-sectional view of a region of a semiconductor device according to an example embodiment.

The semiconductor device according to an example embodiment shown in FIG. 21 mostly corresponds to the semiconductor device according to an example embodiment shown in FIG. 14 so the description thereof will be omitted and the differences will be mainly described. In addition, the same or similar reference numerals are used for constituent elements that are identical or similar to those of the previous example embodiment. The present example embodiment is partially different from the previous example embodiment in that the third capacitor electrode and the fourth capacitor electrode are further included, which will be described below.

As shown in FIG. 21, the semiconductor device includes a first capacitor electrode 6510, a second capacitor electrode 6520, and a first dielectric layer 6542 disposed therebetween. The semiconductor device may further include a third capacitor electrode 6530, a fourth capacitor electrode 6540, a second dielectric layer 6544, and a third dielectric layer 6546. The second capacitor electrode 6520 and the third capacitor electrode 6530 may overlap each other with the second dielectric layer 6544 therebetween to configure the capacitor. The third capacitor electrode 6530 and the fourth capacitor electrode 6540 may overlap each other with the third dielectric layer 6546 therebetween to configure the capacitor.

The semiconductor device includes the second substrate 110, and the second substrate 110 includes a first layer 110a, a second layer 110b, a third layer 110c, and a fourth layer 110d that are sequentially stacked. The second layer 110b may be disposed on the first layer 110a, the third layer 110c may be disposed on the second layer 110b, and the fourth layer 110d may be disposed on the third layer 110c. That is, a bottom surface of the third layer 110c may contact the upper side of the second layer 110b, and a bottom surface of the fourth layer 110d may contact the upper side of the third layer 110c. The first layer 110a, the second layer 110b, the third layer 110c, and the fourth layer 110d may respectively include a conductive material. The first layer 110a, the second layer 110b, the third layer 110c, and the fourth layer 110d may include the same material, or may include materials of which at least a portion is different.

The third capacitor electrode 6530 may be disposed on the same layer as the third layer 110c of the second substrate 110. The third capacitor electrode 6530 may include the same material as the third layer 110c of the second substrate 110, and may be formed in the same process. The third capacitor electrode 6530 may have a thickness that is substantially equivalent to the third layer 110c of the second substrate 110.

The semiconductor device may further include a third voltage line 6555. The third voltage line 6555 may be disposed on the same layer as the first wire portion, for example, the floating electrode 230a. The third voltage line 6555 may be disposed on the same layer as the first voltage line 6551 and the second voltage line 6553. The third capacitor electrode 6530 may be connected to the third voltage line 6555. The third capacitor electrode 6530 may receive the third voltage through the third voltage line 6555. The third voltage may be a constant voltage.

The fourth capacitor electrode 6540 may be disposed on the same layer as the fourth layer 110d of the second substrate 110. The fourth capacitor electrode 6540 may include the same material as the fourth layer 110d of the second substrate 110, and may be formed in the same process. The fourth capacitor electrode 6540 may have a thickness that is substantially equivalent to the fourth layer 110d of the second substrate 110.

The semiconductor device may further include a fourth voltage line 6557. The fourth voltage line 6557 may be disposed on the same layer as the first wire portion, for example, the floating electrode 230a. The fourth voltage line 6557 may be disposed on the same layer as the first voltage line 6551, the second voltage line 6553, and the third voltage line 6555. The fourth capacitor electrode 6540 may be connected to the fourth voltage line 6557. The fourth capacitor electrode 6540 may receive the fourth voltage through the fourth voltage line 6557. The fourth voltage may be a constant voltage.

The semiconductor device may obtain sufficient capacity of the capacitor by forming the capacitor electrodes disposed on many layers. In this instance, the process may be simplified and the integration may be increased by forming first to fourth capacitors in the same process as the second substrate including layers.

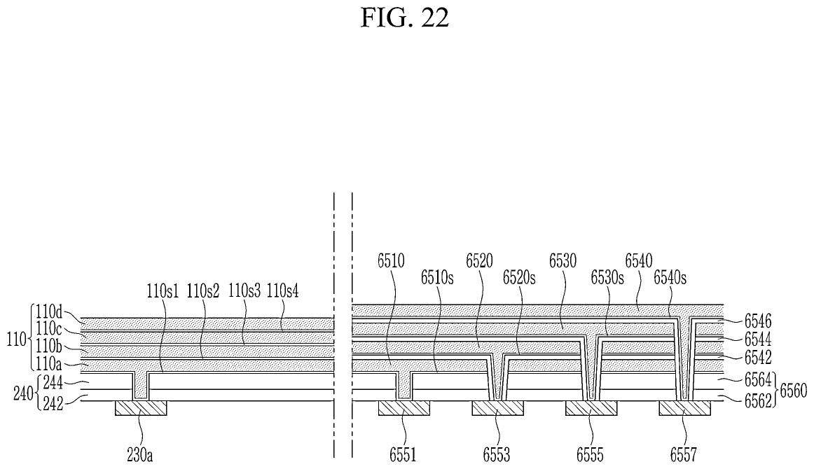

A semiconductor device according to an example embodiment will now be described with reference to FIG. 22.

FIG. 22 shows a cross-sectional view of a region of a semiconductor device according to an example embodiment.

The semiconductor device according to an example embodiment shown in FIG. 22 mostly corresponds to the semiconductor device according to an example embodiment shown in FIG. 21 so the description thereof will be omitted and the differences will be mainly described. In addition, the same or similar reference numerals are used for constituent elements that are identical or similar to those of the previous example embodiment. The present example embodiment is partially different from the previous example embodiment in that the barrier layer is disposed below the first to fourth capacitor electrodes, which will be described below.

As shown in FIG. 22, the semiconductor device includes a first capacitor electrode 6510, a second capacitor electrode 6520, a third capacitor electrode 6530, and a fourth capacitor electrode 6540. A first barrier layer 6510s may be further disposed below the first capacitor electrode 6510, and a second barrier layer 6520s may be further disposed below the second capacitor electrode 6520. A third barrier layer 6530s may be further disposed below the third capacitor electrode 6530, and a fourth barrier layer 6540s may be further disposed below the fourth capacitor electrode 6540. The first barrier layer 6510s, the second barrier layer 6520s, the third barrier layer 6530s, and the fourth barrier layer 6540s may include a conductive material, for example, they may include a metal nitride. For example, the first barrier layer 6510s, the second barrier layer 6520s, the third barrier layer 6530s, and the fourth barrier layer 6540s may include a titanium nitride.

In the previous example embodiment, the first capacitor electrode 6510 may contact the first voltage line 6551, the second capacitor electrode 6520 may contact the second voltage line 6553, the third capacitor electrode 6530 may contact the third voltage line 6555, and the fourth capacitor electrode 6540 may contact the fourth voltage line 6557. In the present example embodiment, a first barrier layer 6510s may be disposed between the first capacitor electrode 6510 and the first voltage line 6551. The first barrier layer 6510s may be disposed between the first capacitor electrode 6510 and the insulation layer 6560. A second barrier layer 6520s may be disposed between the second capacitor electrode 6520 and the second voltage line 6553. The second barrier layer 6520s may be disposed between the second capacitor electrode 6520 and the first dielectric layer 6542. A third barrier layer 6530s may be disposed between the third capacitor electrode 6530 and the third voltage line 6555. The third barrier layer 6530s may be disposed between the third capacitor electrode 6530 and the second dielectric layer 6544. A third barrier layer 6530s may be disposed between the fourth capacitor electrode 6540 and the fourth voltage line 6557. The third barrier layer 6530s may be disposed between the fourth capacitor electrode 6540 and the third dielectric layer 6546.

A first dummy barrier layer 110s1 may be further disposed below the first layer 110a of the second substrate 110. The first dummy barrier layer 110s1 may be disposed on the same layer as the first barrier layer 6510s. The first dummy barrier layer 110s1 may include the same material as the first barrier layer 6510s, and may be formed in the same process. The first dummy barrier layer 110s1 may be disposed between the first layer 110a of the second substrate 110 and the floating electrode 230a. The first dummy barrier layer 110s1 may be disposed between the second substrate 110 and the insulation layer 240.

A second dummy barrier layer 110s2 may be further disposed below the second layer 110b of the second substrate 110. The second dummy barrier layer 110s2 may be disposed on the same layer as the second barrier layer 6520s. The second dummy barrier layer 110s2 may include the same material as the second barrier layer 6520s, and may be formed in the same process. The second dummy barrier layer 110s2 may be disposed between the first layer 110a and the second layer 110b of the second substrate 110.

A third dummy barrier layer 110s3 may be further disposed below the third layer 110c of the second substrate 110. The third dummy barrier layer 110s3 may be disposed on the same layer as the third barrier layer 6530s. The third dummy barrier layer 110s3 may include the same material as the third barrier layer 6530s, and may be formed in the same process. The third dummy barrier layer 110s3 may be disposed between the second layer 110b and the third layer 110c of the second substrate 110.

A fourth dummy barrier layer 110s4 may be further disposed below the fourth layer 110d of the second substrate 110. The fourth dummy barrier layer 110s4 may be disposed on the same layer as the fourth barrier layer 6540s. The fourth dummy barrier layer 110s4 may include the same material as the fourth barrier layer 6540s, and may be formed in the same process. The fourth dummy barrier layer 110s4 may be disposed between the third layer 110c and the fourth layer 110d of the second substrate 110.

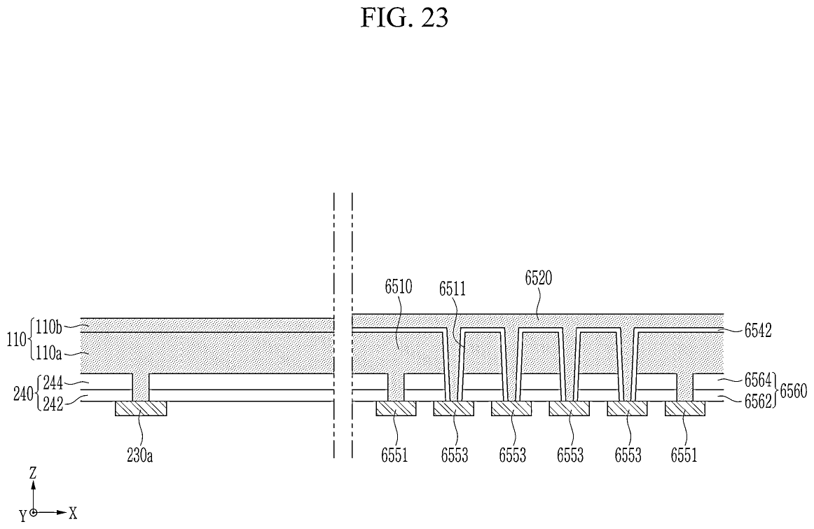

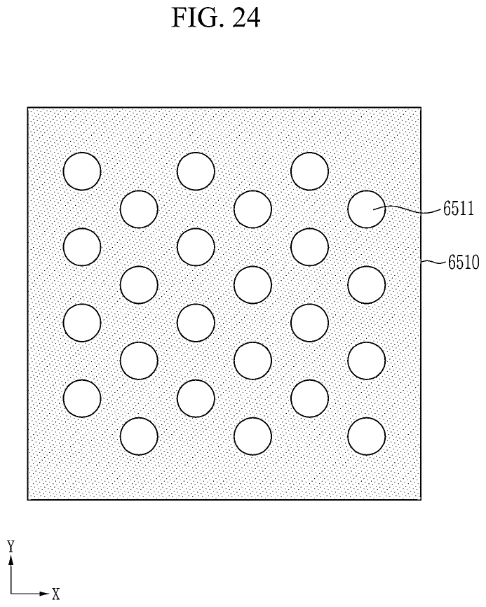

A semiconductor device according to an example embodiment will now be described with reference to FIG. 23 and FIG. 24.

FIG. 23 shows a cross-sectional view of a region of a semiconductor device according to an example embodiment, and FIG. 24 shows a top plan view of some constituent elements of a semiconductor device according to an example embodiment. FIG. 24 shows a planar shape of a first capacitor electrode.

The semiconductor device according to an example embodiment shown in FIG. 23 and FIG. 24 mostly corresponds to the semiconductor device according to an example embodiment shown in FIG. 14 so the description thereof will be omitted and the differences will be mainly described. In addition, the same or similar reference numerals are used for constituent elements that are identical or similar to those of the previous example embodiment. The present example embodiment is partially different from the previous example embodiment in that the thickness of the first capacitor electrode is relatively great, which will be described below.

As shown in FIG. 23, the semiconductor device includes a first capacitor electrode 6510, a second capacitor electrode 6520, and a first dielectric layer 6542 disposed therebetween. The first capacitor electrode 6510 and the second capacitor electrode 6520 may overlap each other with the first dielectric layer 6542 therebetween to configure the capacitor.

In the previous example embodiment, the thickness of the first capacitor electrode 6510 may be substantially equivalent to the thickness of the second capacitor electrode 6520. In the present example embodiment, the thickness of the first capacitor electrode 6510 may be different from the thickness of the second capacitor electrode 6520. The first capacitor electrode 6510 may be thicker than the second capacitor electrode 6520. In this instance, the thickness represents the thickness of the first capacitor electrode 6510 in the Z-axis direction on a portion where the first capacitor electrode 6510 and the second capacitor electrode 6520 overlap each other in the Z-axis direction, and the thickness of the second capacitor electrode 6520 in the Z-axis direction. In a portion where the first capacitor electrode 6510 and the second capacitor electrode 6520 do not overlap in the Z-axis direction, the thickness of the second capacitor electrode 6520 in the Z-axis direction may be greater than the thickness of the first capacitor electrode 6510.

The semiconductor device includes the second substrate 110, and the second substrate 110 includes the first layer 110a and the second layer 110b. The first layer 110a may be thicker than the second layer 110b. The thickness of the first layer 110a may be substantially equivalent to the thickness of the first capacitor electrode 6510, and the thickness of the second layer 110b may be substantially equivalent to the thickness of the second capacitor electrode 6520.

The semiconductor device may include first voltage lines 6551, and the first capacitor electrodes 6510 may be connected to the first voltage lines 6551. The same first voltage may be applied to the first voltage lines 6551. The semiconductor device may include a second voltage lines 6553, and the second capacitor electrode 6520 may be connected to the second voltage lines 6553. The same second voltage may be applied to the second voltage lines 6553.

Regarding the shape of the first capacitor electrode 6510 in a plan view with reference to FIG. 24, openings 6511 disposed at regular intervals may be formed in the first capacitor electrode 6510. The openings 6511 may be disposed at respective apexes of a hexagon. However, dispositions of the openings 6511 are not limited thereto and may be modifiable in many ways. For example, the openings 6511 may be disposed at regular intervals in the X-axis direction and the Y-axis direction. Further, the openings 6511 may be circular in a plan view. However, the planar shape of the openings 6511 is not limited thereto and may be modifiable in many ways. For example, the planar shape of the openings 6511 may have polygonal shapes such as a quadrangle.

The openings 6511 of the first capacitor electrode 6510 may respectively overlap the second voltage lines 6553. The sidewalls of the openings 6511 may be covered by the first dielectric layer 6542. An opening overlapping the second voltage line 6553 may be formed in the first dielectric layer 6542, and the second capacitor electrode 6520 may be connected to the second voltage line 6553 through the openings 6511 of the first capacitor electrode 6510 and the opening of the first dielectric layer 6542.

In the previous example embodiment, the capacitor may be generally formed on a portion where the first capacitor electrode 6510 and the second capacitor electrode 6520 overlap in the vertical direction (Z-axis direction in the drawing). In the present example embodiment, by forming the first capacitor electrode 6510 to be relatively thick, the capacitor may be formed on a portion where the first capacitor electrode 6510 and the second capacitor electrode 6520 overlap in the horizontal direction (X-axis direction or Y-axis direction in the drawing). Further, sufficient capacity of the capacitor may be obtained by forming the openings 6511 in the first capacitor electrode 6510 and disposing the second capacitor electrode 6520 inside the openings 6511.

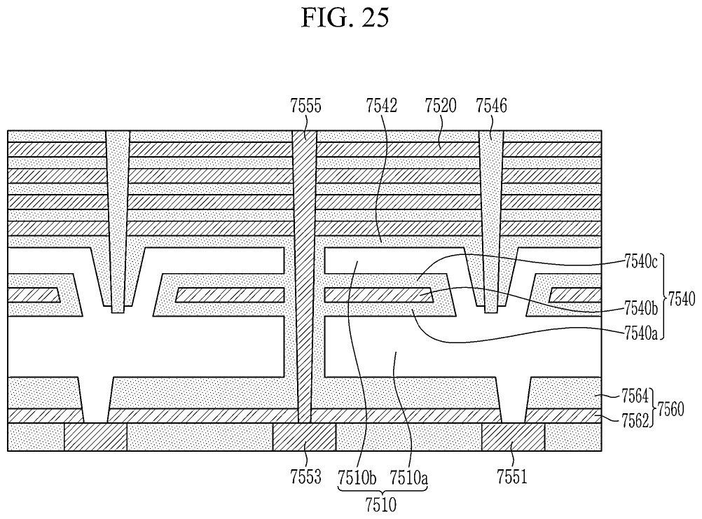

A semiconductor device according to an example embodiment will now be described with reference to FIG. 25.

FIG. 25 shows a cross-sectional view of a region of a semiconductor device according to an example embodiment. FIG. 25 shows a capacitor region of a semiconductor device according to an example embodiment, and the circuit region and the cell region are substantially equivalent to what are described according to an example embodiment with reference to FIG. 1, which will be referred to in the following description.

The semiconductor device according to an example embodiment shown in FIG. 25 mostly corresponds to the semiconductor device according to an example embodiment shown in FIG. 1 to FIG. 3 so the description thereof will be omitted and the differences will be mainly described. In addition, the same or similar reference numerals are used for constituent elements that are identical or similar to those of the previous example embodiment. The present example embodiment is partially different from the previous example embodiment in that the second capacitor electrode may be disposed on the same layer as the gate electrode, which will be described below.

As shown in FIG. 25, the semiconductor device includes a first capacitor electrode 7510, a second capacitor electrode 7520, and a first dielectric layer 7542 disposed therebetween. The first capacitor electrode 7510 and the second capacitor electrode 7520 overlap each other with the first dielectric layer 7542 therebetween to configure the capacitor.

At least a portion of the first capacitor electrode 7510 may be disposed on the same layer as the second substrate 110 of FIG. 1. Another portion of the first capacitor electrode 7510 may be disposed on the same layer as the second horizontal conductive layer 114 of FIG. 1. The first capacitor electrode 7510 may include a first layer 7510a and a second layer 7510b. The first layer 7510a of the first capacitor electrode 7510 may be disposed on the same layer as the second substrate 110 of FIG. 1. The first layer 7510a of the first capacitor electrode 7510 may include the same material as the second substrate 110 of FIG. 1, and may be formed in the same process. The second layer 7510b of the first capacitor electrode 7510 may be disposed on the same layer as the second horizontal conductive layer 114 of FIG. 1. The second layer 7510b of the first capacitor electrode 7510 may include the same material as the second horizontal conductive layer 114 of FIG. 1, and may be formed in the same process. The second layer 7510b of the first capacitor electrode 7510 may be disposed on the first layer 7510a. The second layer 7510b of the first capacitor electrode 7510 may be connected to the first layer 7510a.

An insulation layer 7540 may be disposed between the first layer 7510a and the second layer 7510b of the first capacitor electrode 7510. The second layer 7510b of the first capacitor electrode 7510 may be connected to the first layer 7510a through the opening formed in the insulation layer 7540. The insulation layer 7540 may include a lower layer 7540a, an intermediate layer 7540b, and an upper layer 7540c. In this instance, the intermediate layer 7540b may be disposed on the lower layer 7540a, and the upper layer 7540c may be disposed on the intermediate layer 7540b. That is, the intermediate layer 7540b may be disposed between the lower layer 7540a and the upper layer 7540c. The insulation layer 7540 may include various types of insulating materials. For example, the lower layer 7540a and the upper layer 7540c may include a silicon oxide, and the intermediate layer 7540b may include a silicon nitride.

The insulation layer 7540 may be disposed on the same layer as the horizontal insulation layer 116. The insulation layer 7540 may include the same material as the horizontal insulation layer 116, and may be formed in the same process. The lower layer 7540a of the insulation layer 7540 may be disposed on the same layer as the lower layer 116a of the horizontal insulation layer 116. The intermediate layer 7540b of the insulation layer 7540 may be disposed on the same layer as the intermediate layer 116b of the horizontal insulation layer 116. The upper layer 7540c of the insulation layer 7540 may be disposed on the same layer as the upper layer 116c of the horizontal insulation layer 116.

The semiconductor device may further include a first voltage line 7551. The first voltage line 7551 may be disposed on the same layer as the first wire portion 230 of FIG. 1. The first voltage line 7551 may include the same material as the first wire portion 230 of FIG. 1, and may be formed in the same process. The first voltage line 7551 may receive the first voltage. The first capacitor electrode 7510 may be connected to the first voltage line 7551. The first capacitor electrode 7510 may receive the first voltage through the first voltage line 7551.

An insulation layer 7560 may be disposed between the first capacitor electrode 7510 and the first voltage line 7551. The first capacitor electrode 7510 may be connected to the first voltage line 7551 through the opening formed in the insulation layer 7560. In this instance, the first layer 7510a of the first capacitor electrode 7510 may be directly connected to the first voltage line 7551. The second layer 7510b of the first capacitor electrode 7510 may be connected to the first voltage line 7551 through the first layer 7510a. The insulation layer 7560 disposed between the first capacitor electrode 7510 and the first voltage line 7551 may be disposed on the same layer as the insulation layer 240 of FIG. 1 disposed between the second substrate 110 of FIG. 1 and the first wire portion 230 of FIG. 1. The insulation layer 7560 may be a single layer or a multilayer. For example, the insulation layer 7560 may include a lower insulation layer 7562, and an upper insulation layer 7564 disposed on the lower insulation layer 7562. The insulation layer 7560 may include various types of insulating materials. For example, the lower insulation layer 7562 may include a silicon nitride, and the upper insulation layer 7564 may include a silicon oxide.

The second capacitor electrode 7520 may be disposed on the same layer as the gate electrode 130 of FIG. 1. The second capacitor electrode 7520 may include the same material as the gate electrode 130 of FIG. 1, and may be formed in the same process. The first dielectric layer 7542 may be disposed on the same layer as the cell insulation layer 132 of FIG. 1. The first dielectric layer 7542 may include the same material as the cell insulation layer 132 of FIG. 1, and may be formed in the same process. As the cell insulation layer 132 of FIG. 1 and the gate electrode 130 of FIG. 1 are alternately stacked in the cell region, the first dielectric layer 7542 and the second capacitor electrode 7520 are alternately stacked in the capacitor region. In this instance, the stacking number of the first dielectric layers 7542 and the second capacitor electrodes 7520 may be equivalent to/different from the number of the stacking number of the cell insulation layer 132 of FIG. 1 and the gate electrode 130 of FIG. 1.

The semiconductor device may further include a second voltage line 7553. The second voltage line 7553 may be disposed on the same layer as the first voltage line 7551. The second voltage line 7553 may include the same material as the first voltage line 7551, and may be formed in the same process. The second voltage line 7553 may be disposed on the same layer as the first wire portion 230 of FIG. 1. The second voltage line 7553 may receive the second voltage line. The second capacitor electrode 7520 may be connected to the second voltage line 7553. The second capacitor electrode 7520 may receive the second voltage through the second voltage line 7553.

The semiconductor device may further include a connection structure 7555 for connecting the second capacitor electrode 7520 and the second voltage line 7553. The connection structure 7555 may extend in the same direction as the channel structure CH of FIG. 1. The second capacitor electrode 7520 may be connected to the second voltage line 7553 through the connection structure 7555.

The insulation layers 7540 and 7560 and the first capacitor electrode 7510 may be disposed between the second capacitor electrode 7520 and the second voltage line 7553. An opening may be formed in the first capacitor electrode 7510, and the first dielectric layer 7542 may fill the opening. The connection structure 7555 may pass through the first dielectric layer 7542 and may connect the second capacitor electrode 7520 and the second voltage line 7553.

The semiconductor device may further include a dummy separation structure 7546 passing through the stacking structure of the first dielectric layer 7542 and the second capacitor electrode 7520. The dummy separation structure 7546 may be disposed on the same layer as the separation structure 146 of FIG. 1. The dummy separation structure 7546 may include the same material as the separation structure 146 of FIG. 1, and may be formed in the same process.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor in the capacitor region by use of the constituent elements disposed in the circuit region and the cell region.

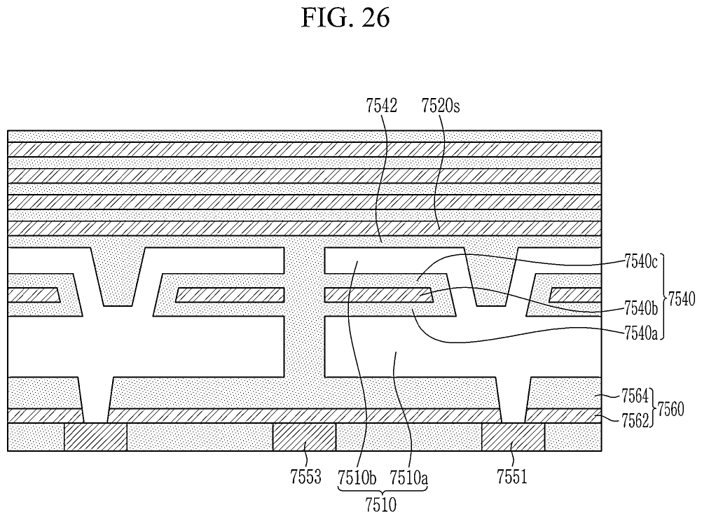

A method for manufacturing semiconductor device according to an example embodiment will now be described with reference to FIG. 26 to FIG. 30.

FIG. 26 to FIG. 30 sequentially show processing cross-sectional views of part of a method for manufacturing a semiconductor device according to an example embodiment. FIG. 26 to FIG. 30 show a process for manufacturing a semiconductor device according to an example embodiment shown in FIG. 25.

As shown in FIG. 26, the first voltage line 7551 and the second voltage line 7553 are formed by using a conductive material. For example, the first voltage line 7551 and the second voltage line 7553 may be formed by depositing a conductive material and patterning the same. In this instance, the first wire portion 230 of FIG. 1 may be formed together.

An insulation layer 7560 is formed on the first voltage line 7551 and the second voltage line 7553 by sequentially stacking the lower insulation layer 7562 and the upper insulation layer 7564 by use of an insulating material. In this instance, the lower insulation layer 7562 may include a silicon nitride, and the upper insulation layer 7564 may include a silicon oxide. However, materials of the lower insulation layer 7562 and the upper insulation layer 7564 are not limited thereto, and may be modifiable in many ways.

An opening for exposing at least a portion of the first voltage line 7551 is formed by patterning the insulation layer 7560. A first layer 7510a of the first capacitor electrode 7510 is formed on the insulation layer 7560 by using a conductive material. The first layer 7510a of the first capacitor electrode 7510 may be connected to the first voltage line 7551 through the opening formed in the insulation layer 7560.

The lower layer 7540a, the intermediate layer 7540b, and the upper layer 7540c are stacked on the first layer 7510a of the first capacitor electrode 7510 to form the insulation layer 7540. In this instance, the lower layer 7540a and the upper layer 7540c may include a silicon oxide, and the intermediate layer 7540b may include a silicon nitride. However, the materials of the lower layer 7540a, the intermediate layer 7540b, and the upper layer 7540c are not limited thereto, and may be modifiable in many ways.

An opening for exposing at least a portion of the first layer 7510a of the first capacitor electrode 7510 is formed by patterning the insulation layer 7540. A second layer 7510b of the first capacitor electrode 7510 is formed on the insulation layer 7540 by using a conductive material. The second layer 7510b of the first capacitor electrode 7510 may be connected to the first layer 7510a of the first capacitor electrode 7510 through the opening formed in the insulation layer 7540.

The first dielectric layer 7542 and a sacrificial layer 7520s are alternately stacked on the first capacitor electrode 7510. An opening overlapping the second voltage line 7553 may be formed in the first capacitor electrode 7510, and the opening of the first capacitor electrode 7510 may be filled with the first dielectric layer 7542.

A portion on which the second layer 7510b of the first capacitor electrode 7510 contacts the first layer 7510a may be disposed in the opening of the insulation layer 7540 so the portion of the second layer 7510 contacting the first layer 7510a may have a height difference from other portions. Hence, the upper side of the first dielectric layer 7542 disposed on the first capacitor electrode 7510 may not be planar. To planarize the upper side of the first dielectric layer 7542, a chemical mechanical polishing (CMP) process may be performed.

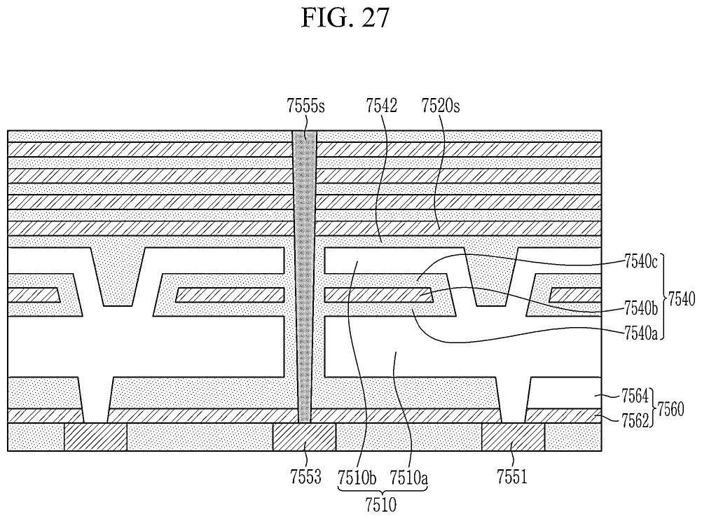

As shown in FIG. 27, an opening passing through the stacking structure of the first dielectric layer 7542 and the sacrificial layer 7520s is formed, and a sacrificial structure 7555s filling the opening is formed. In this instance, the opening may pass through the first dielectric layer 7542 filling the opening of the first capacitor electrode 7510, and may pass through the insulation layers 7540 and 7560. The opening may overlap the second voltage line 7553. Therefore, at least a portion of the second voltage line 7553, for example, a portion of the upper side may be exposed by the opening. The sacrificial structure 7555s may contact the upper side of the second voltage line 7553. The sacrificial structure 7555s may include polysilicon. However, it is not limited to this, and the material of the sacrificial structure 7555s may be modifiable in many ways.

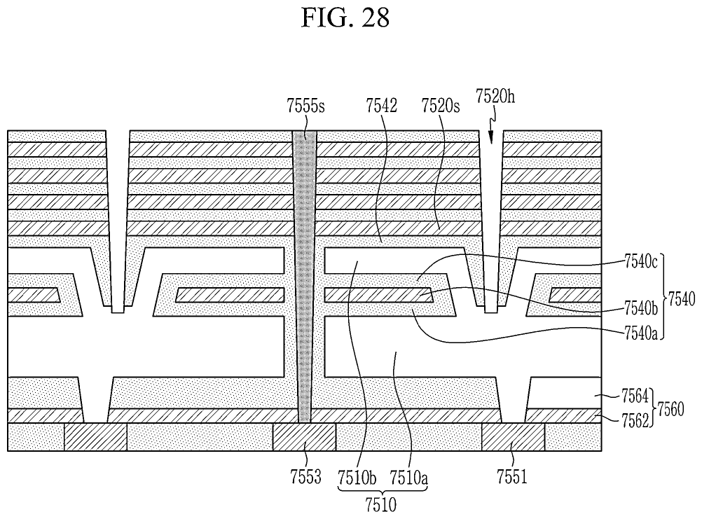

As shown in FIG. 28, an opening 7520h passing through the stacking structure of the first dielectric layer 7542 and the sacrificial layer 7520s is formed. At least a portion of the sacrificial layer 7520s may be exposed by the opening 7520h. For example, a side of the sacrificial layer 7520s may be exposed to the outside. The opening 7520h may overlap the first capacitor electrode 7510. When the first dielectric layer 7542 and the sacrificial layer 7520s are etched so as to form the opening 7520h, at least a portion of the first capacitor electrode 7510 may be etched together. That is, a groove may be formed in the upper side of the first capacitor electrode 7510.

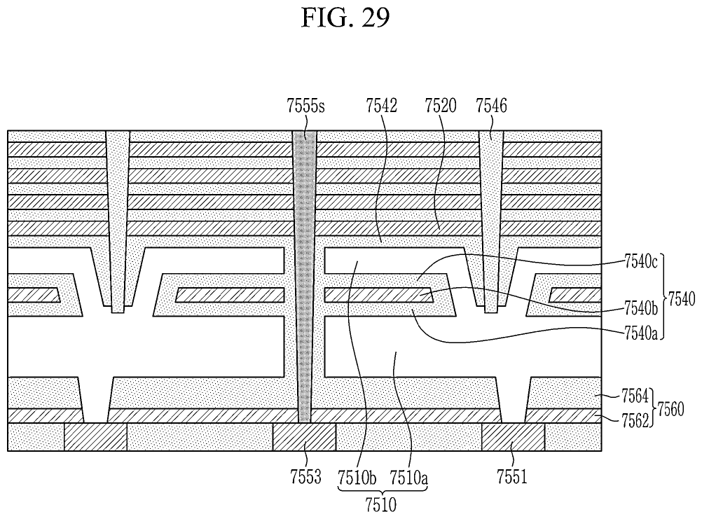

As shown in FIG. 29, the exposed sacrificial layer 7520s is removed by the opening 7520h. In this instance, in the etching process for removing the sacrificial layer 7520s, the first dielectric layer 7542 may not be removed but may remain by a difference of an etching ratio of the sacrificial layer 7520s and the first dielectric layer 7542. Therefore, a space may be generated among the first dielectric layers 7542 with many layers. To fill the space, the conductive material is deposited and the second capacitor electrode 7520 is formed. Therefore, the stacking structure of the first dielectric layer 7542 and the second capacitor electrode 7520 may be formed. In this instance, the gate electrode 130 of FIG. 1 may be formed together.

An opening passing through the stacking structure of the first dielectric layer 7542 and the second capacitor electrode 7520 is formed, and a dummy separation structure 7546 filling the opening is formed. The dummy separation structure 7546 may include an insulating material. For example, the dummy separation structure 7546 may include a silicon oxide. In this instance, the separation structure 146 of FIG. 1 may be formed together.

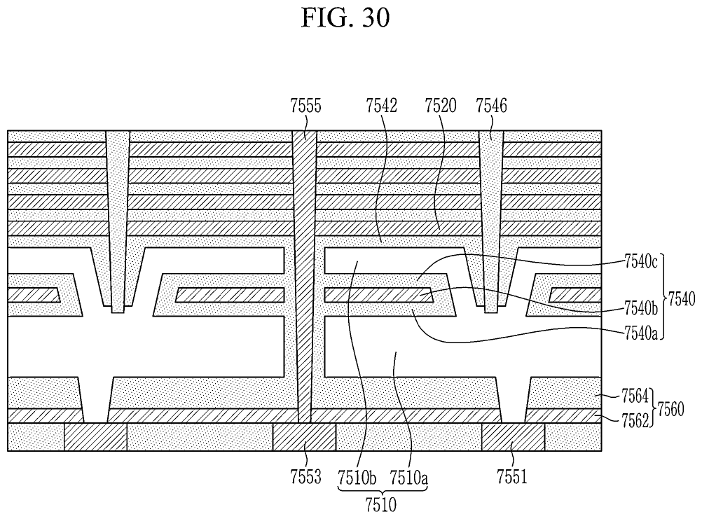

As shown in FIG. 30, the sacrificial structure 7555s is removed. For example, the sacrificial structure 7555s may be removed by performing the etching process by use of an etching solution for selectively removing the sacrificial structure 7555s. A space may be generated on the portion where the sacrificial structure 7555s is disposed. The connection structure 7555 is formed to fill the space. The connection structure 7555 may be connected to the second capacitor electrode 7520. For example, the connection structure 7555 may be connected to a side of the second capacitor electrode 7520. The connection structure 7555 may be connected to the second voltage line 7553. For example, the connection structure 7555 may be connected to the upper side of the second voltage line 7553. The second capacitor electrode 7520 may be connected to the second voltage line 7553 through the connection structure 7555. The connection structure 7555 may be insulated from the first capacitor electrode 7510 by the first dielectric layer 7542.

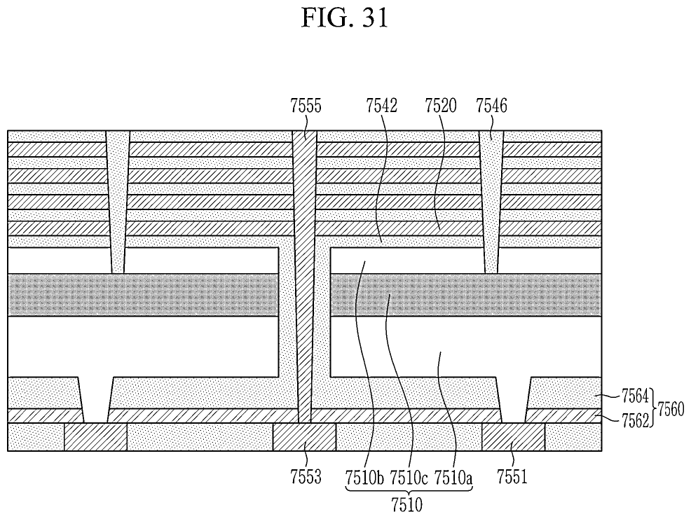

A semiconductor device according to an example embodiment will now be described with reference to FIG. 31.

FIG. 31 shows a cross-sectional view of a region of a semiconductor device according to an example embodiment.

The example embodiment shown in FIG. 31 mostly corresponds to the example embodiment shown in FIG. 25, the description thereof will be omitted and the differences will be mainly described. In addition, the same or similar reference numerals are used for constituent elements that are identical or similar to those of the previous example embodiment. The present example embodiment is different from the previous example embodiment in that a third layer is further disposed between the first layer and the second layer of the first capacitor electrode, which will now be described.

As shown in FIG. 31, the semiconductor device includes a first capacitor electrode 7510, a second capacitor electrode 7520, and a first dielectric layer 7542 disposed therebetween. The first capacitor electrode 7510 and the second capacitor electrode 7520 may overlap each other with the first dielectric layer 7542 to configure the capacitor.

In the previous example embodiment, the first capacitor electrode 7510 includes a first layer 7510a and a second layer 7510b, and an insulation layer 7540 of FIG. 25 may be disposed between the first layer 7510a and the second layer 7510b. In the present example embodiment, the first capacitor electrode 7510 includes a first layer 7510a, a second layer 7510b, and a third layer 7510c. Not the insulation layer but the third layer 7510c may be disposed between the first layer 7510a and the second layer 7510b of the first capacitor electrode 7510. The second layer 7510b may be disposed on the first layer 7510a of the first capacitor electrode 7510, and a third layer 7510c may be disposed on the second layer 7510b. The first layer 7510a, the second layer 7510b, and the third layer 7510c of the first capacitor electrode 7510 may include conductive materials. For example, the first layer 7510a, the second layer 7510b, and the third layer 7510c of the first capacitor electrode 7510 may include polysilicon to which impurities are doped. However, without being limited thereto, the materials of the first layer 7510a, the second layer 7510b, and the third layer 7510c of the first capacitor electrode 7510 are changeable in many ways. The first layer 7510a, the second layer 7510b, and the third layer 7510c of the first capacitor electrode 7510 may include the same material, or at least some of them may include different materials.

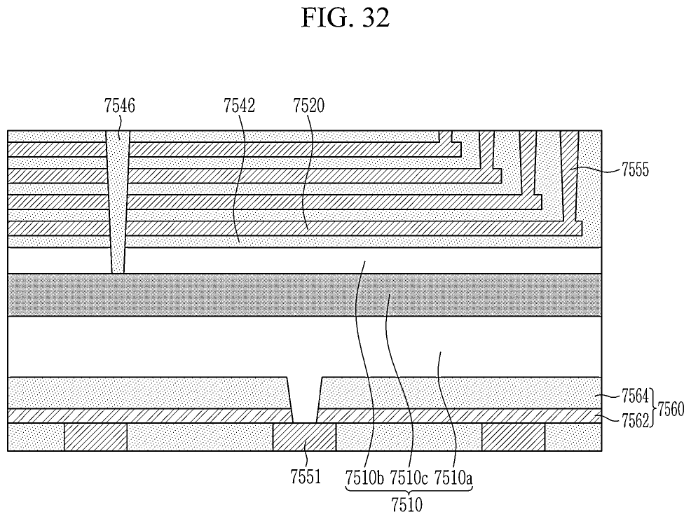

A semiconductor device according to an example embodiment will now be described with reference to FIG. 32.

FIG. 32 shows a cross-sectional view of a region of a semiconductor device according to an example embodiment.

The semiconductor device according to an example embodiment shown in FIG. 32 mostly corresponds to the semiconductor device according to an example embodiment shown in FIG. 31 so the description thereof will be omitted and the differences will be mainly described. In addition, the same or similar reference numerals are used for constituent elements that are identical or similar to those of the previous example embodiment. The present example embodiment is partially different from the previous example embodiment in that the second voltage line is not disposed on the same layer as the first voltage line, which will be described below.

As shown in FIG. 32, the semiconductor device includes a first capacitor electrode 7510, a second capacitor electrode 7520, and a first dielectric layer 7542 disposed therebetween. The first capacitor electrode 7510 and the second capacitor electrode 7520 may overlap each other with the first dielectric layer 7542 to configure the capacitor.

In the previous example embodiment, the first voltage line 7551 and the second voltage line 7553 of FIG. 25 may be disposed on the same layer. In the present example embodiment, the first voltage line 7551 and the second voltage line may be disposed on different layers. Although not shown, the second voltage line may be disposed on the same layer as the second wire portion 180 of FIG. 1.

Further, ends of the second capacitor electrodes 7520 of many layers may be formed to be stepwise. The semiconductor device may include a connection structure 7555 connected to the ends of the second capacitor electrodes 7520 of the respective layers. Although not shown, the connection structure 7555 may be connected to the second voltage line. That is, the second capacitor electrode 7520 may be connected to the second voltage line through the connection structure 7555, and may receive the second voltage.

A semiconductor device according to an example embodiment will now be described with reference to FIG. 33.

FIG. 33 shows a cross-sectional view of a region of a semiconductor device according to an example embodiment. FIG. 33 shows part of a cell region and a capacitor region of a semiconductor device according to an example embodiment.

The example embodiment shown in FIG. 33 mostly corresponds to the example embodiment shown in FIG. 25 so the description thereof will be omitted and the differences will be mainly described. In addition, the same or similar reference numerals are used for constituent elements that are identical or similar to those of the previous example embodiment. The present example embodiment is partially different from the previous example embodiment in that the cell region is upside down.

Although not shown, the semiconductor device may have a chip-to-chip structure by a wafer bonding method. The circuit region of the semiconductor device according to an example embodiment is not shown, and the second substrate 110, the gate stacking structure 120, and the channel structure CH may be disposed in the cell region. A first capacitor electrode 8510, a second capacitor electrode 8520, and a first dielectric layer 8542 disposed therebetween may be disposed in the capacitor region. The first capacitor electrode 8510 and the second capacitor electrode 8520 may overlap each other with the first dielectric layer 8542 therebetween to configure the first capacitor.

The gate stacking structure 120 includes a cell insulation layer 132 and gate electrode 130 that are alternately stacked. The channel structure CH may pass through the gate stacking structure 120. The channel structure CH may include a channel layer 140, a gate dielectric layer 150, and a core insulation layer 142. The channel layer 140 may be disposed between the gate dielectric layer 150 and the core insulation layer 142. The gate dielectric layer 150 may include a tunneling layer 152, a charge storage layer 154, and a blocking layer 156 sequentially stacked on the channel layer 140. At least a portion of the channel structure CH may be disposed in a groove formed in the second substrate 110. The channel layer 140 may protrude upward compared to the gate dielectric layer 150, and the protrusion of the channel layer 140 may be surrounded by the second substrate 110. An end of the channel layer 140 may contact the second substrate 110.

The semiconductor device may further include a separation structure 146. The separation structure 146 may pass through the channel structure CH, and an end of the separation structure 146 may be disposed in the groove formed in the second substrate 110.

The first capacitor electrode 8510 may be disposed on the same layer as the second substrate 110. The first capacitor electrode 8510 may include the same material as the second substrate 110, and may be formed in the same process. The first capacitor electrode 8510 may be separated from the second substrate 110.

The semiconductor device may further include a first connection electrode 8559a. The first connection electrode 8559a is connected to the first capacitor electrode 8510. Although not shown, the semiconductor device may further include the first voltage line, and the first voltage line may be connected to the first connection electrode 8559a. Therefore, the first capacitor electrode 8510 may be connected to the first voltage line through the first connection electrode 8559a, and may receive the first voltage.

The second capacitor electrode 8520 may be disposed on the same layer as the gate electrode 130. The second capacitor electrode 8520 may include the same material as the gate electrode 130, and may be formed in the same process. The second capacitor electrode 8520 may be separated from the gate electrode 130.

The semiconductor device may further include a connection structure 8555 and a second connection electrode 8559b. The connection structure 8555 is connected to the second capacitor electrode 8520. The connection structure 8555 may extend in the same direction (Z-axis direction in the drawing) as the channel structure CH. The connection structure 8555 may be connected to the second connection electrode 8559b. The second capacitor electrode 8520 may be connected to the second connection electrode 8559b through the connection structure 8555. Although not shown, the semiconductor device may further include a second voltage line, and the second voltage line may be connected to the second connection electrode 8559b. Therefore, the second capacitor electrode 8520 may be connected to the second voltage line through the connection structure 8555 and the second connection electrode 8559b, and may receive the second voltage.

The first dielectric layer 8542 may be disposed between the first capacitor electrode 8510 and the second capacitor electrode 8520. The first dielectric layer 8542 may be disposed on the same layer as the cell insulation layer 132. The first dielectric layer 8542 may include the same material as the cell insulation layer 132, and may be formed in the same process.

The respective electrodes configuring the capacitor disposed in the capacitor region of the semiconductor device, the dielectric layers disposed among them, and the voltage lines connected to the electrodes may be disposed on the same layer as the constituent elements disposed in the circuit region and the cell region. That is, the process may be simplified and the integration may be increased by forming the capacitor in the capacitor region by use of the constituent elements disposed in the circuit region and the cell region.

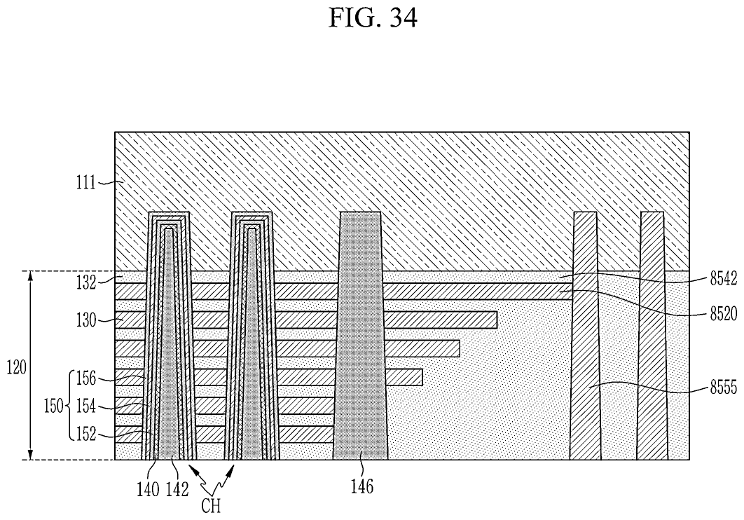

A method for manufacturing a semiconductor device according to an example embodiment will now be described with reference to FIG. 34 to FIG. 39.

FIG. 34 to FIG. 39 sequentially show processing cross-sectional views of part of a method for manufacturing a semiconductor device according to an example embodiment. FIG. 34 to FIG. 39 shows a process for manufacturing a semiconductor device according to an example embodiment shown in FIG. 33.

As shown in FIG. 34, a gate stacking structure 120, a channel structure CH, a separation structure 146, a second capacitor electrode 8520, a first dielectric layer 8542, and a connection structure 8555 are formed on the substrate material layer 111. For example, the insulating material and the sacrificial material may be alternately stacked on the substrate material layer 111, the opening for passing through them may be formed, the channel structure CH may be formed, and the conductive material replacing the sacrificial material may be deposited to form the gate electrode 130 and the second capacitor electrode 8520. The separation structure 146 and the connection structure 8555 may then be formed.

The substrate material layer 111 may be a semiconductor substrate made of a semiconductor material. For example, the substrate material layer 111 may be configured with silicon, epitaxial silicon, germanium, silicon-germanium, a silicon-on-insulator (SOI), or germanium-on-insulator (GOI).

The substrate material layer 111 is overturned so that its bottom side may front upward, the cell region and the circuit region are disposed to face each other, thereby performing the bonding process.

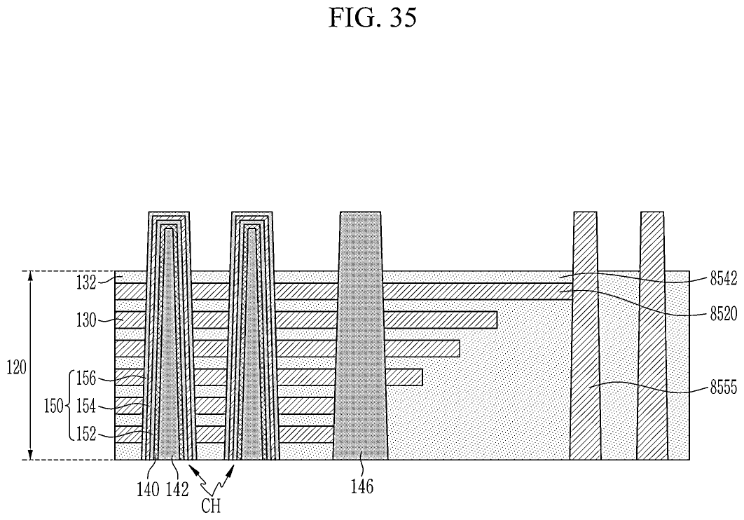

As shown in FIG. 35, the substrate material layer 111 is removed. For example, the substrate material layer 111 may be removed by using one or plural processes of a grinding process, an etching process, and a chemical mechanical polishing process. As the substrate material layer 111 is removed, the ends such as the channel structure CH, the separation structure 146, and the connection structure 8555 may be exposed to the outside. In this instance, the gate dielectric layer 150 of the channel structure CH is exposed to the outside, and the channel layer 140 is surrounded by the gate dielectric layer 150 so it may not be exposed to the outside.

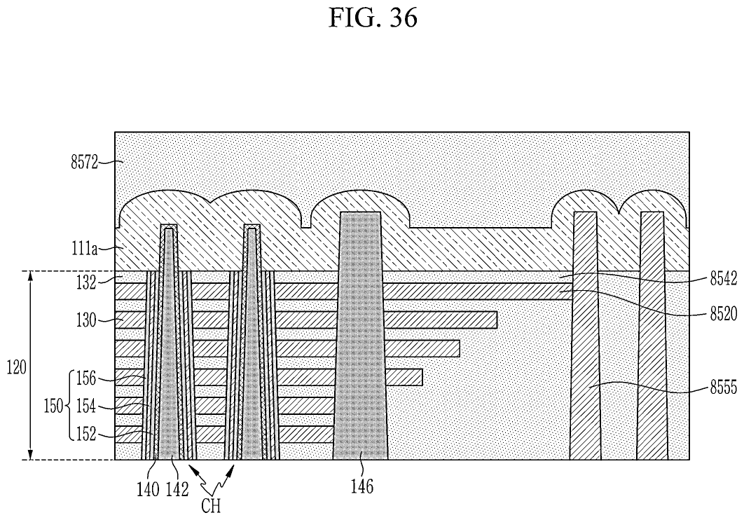

As shown in FIG. 36, a portion of the gate dielectric layer 150 exposed to the outside is removed. For example, the blocking layer 156, the charge storage layer 154, and the tunneling layer 152 of the gate dielectric layer 150 may be sequentially removed by using the etching process. As the exposed portion of the gate dielectric layer 150 is removed, one sides of the gate dielectric layer 150 and the cell insulation layer 132 may be planarized. Further, an end of the channel layer 140 may be exposed to the outside. That is, the channel layer 140 may protrude from the gate dielectric layer 150, and the protrusion of the channel layer 140 may be exposed to the outside.

A conductive material layer 111 a is formed on the gate stacking structure 120, the channel structure CH, the separation structure 146, the first dielectric layer 8542, and the connection structure 8555

The conductive material layer 111 a may include a conductive material. For example, the conductive material layer 111 a may include polysilicon to which impurities are doped. In this instance, the upper side of the conductive material layer 111 a may not be planarized. A height of a portion of the conductive material layer 111a for covering the channel structure CH, the separation structure 146, and the connection structure 8555 may be greater than a height of a portion of the conductive material layer 111a for covering the gate stacking structure 120 and the first dielectric layer 8542.

A first insulation layer 8572 is formed on the conductive material layer 111 a by using an insulating material. The first insulation layer 8572 may include various types of insulating materials. For example, the first insulation layer 8572 may include a silicon oxide.

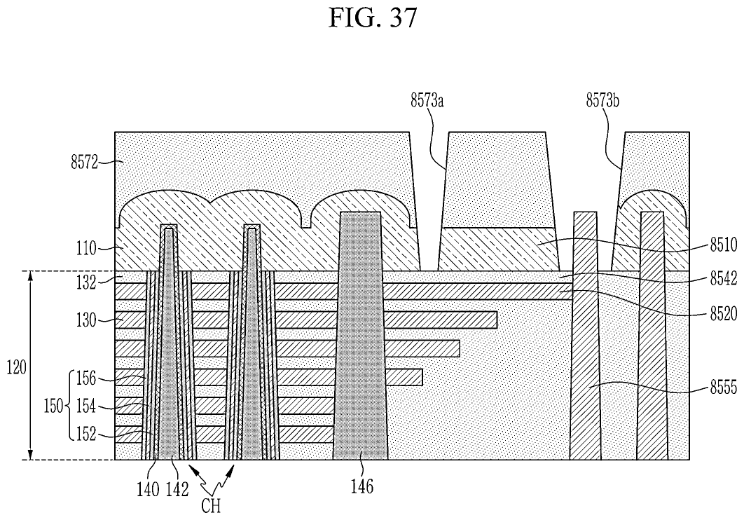

As shown in FIG. 37, a first opening 8573a and a second opening 8573b are formed by patterning the first insulation layer 8572 and the conductive material layer 111a. The first insulation layer 8572 may be etched, and the conductive material layer 111 a may then be etched. The conductive material layer 111 a may be divided into the second substrate 110 and the first capacitor electrode 8510 by the first opening 8573a. An end of the connection structure 8555 may be exposed to the outside by the second opening 8573b. As the conductive material layer 111 a covering the connection structure 8555 is removed, the connection between the connection structure 8555 and the conductive material layer 111 a may be broken.

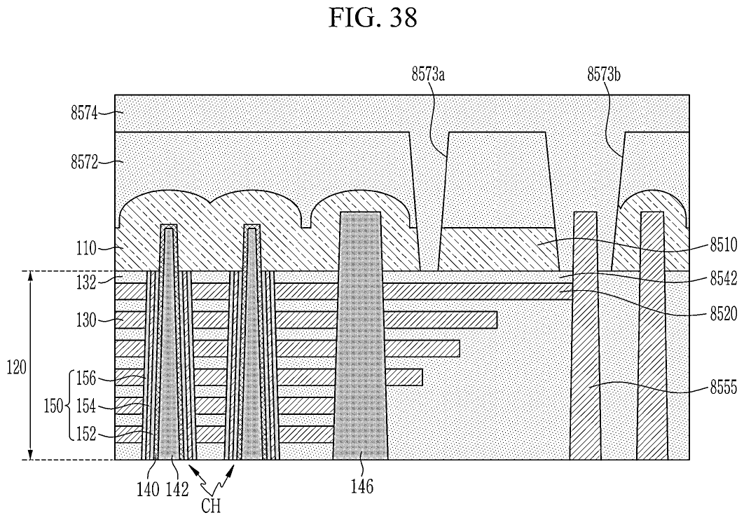

As shown in FIG. 38, a second insulation layer 8574 is formed on first insulation layer 8572 by using an insulating material. The second insulation layer 8574 may include various types of insulating materials. For example, the second insulation layer 8574 may include a silicon oxide. The second insulation layer 8574 may fill the first opening 8573a and the second opening 8573b. Therefore, the second insulation layer 8574 may be disposed between the second substrate 110 and the first capacitor electrode 8510. Further, the second insulation layer 8574 may surround an end of the connection structure 8555.

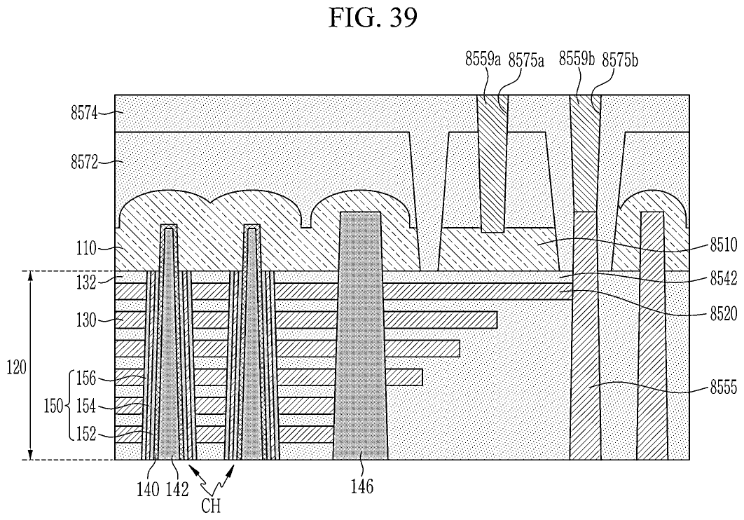

As shown in FIG. 39, a third opening 8575a and a fourth opening 8575b are formed by patterning the first insulation layer 8572 and the second insulation layer 8574. At least a portion of the upper side of the first capacitor electrode 8510 may be exposed to the outside by the third opening 8575a. An upper side of the connection structure 8555 may be exposed to the outside by the fourth opening 8575b.

A first connection electrode 8559a may be formed in the third opening 8575a by using a conductive material, and a second connection electrode 8559b may be formed in the fourth opening 8575b. For example, the conductive material may be deposited on the second insulation layer 8574, and a planarization process may be performed to remain the conductive material disposed in the third opening 8575a and the fourth opening 8575b and remove the conductive material disposed on the upper side of the second insulation layer 8574. The first connection electrode 8559a may be connected to the first capacitor electrode 8510. A first voltage line connected to the first connection electrode 8559a may be formed in a subsequent process. The first capacitor electrode 8510 may receive the first voltage from the first voltage line through the first connection electrode 8559a. The second connection electrode 8559b may be connected to the connection structure 8555. A second voltage line connected to the second connection electrode 8559b may be formed in a subsequent process. The second capacitor electrode 8520 may receive the second voltage from the second voltage line through the second connection electrode 8559b and the connection structure 8555.

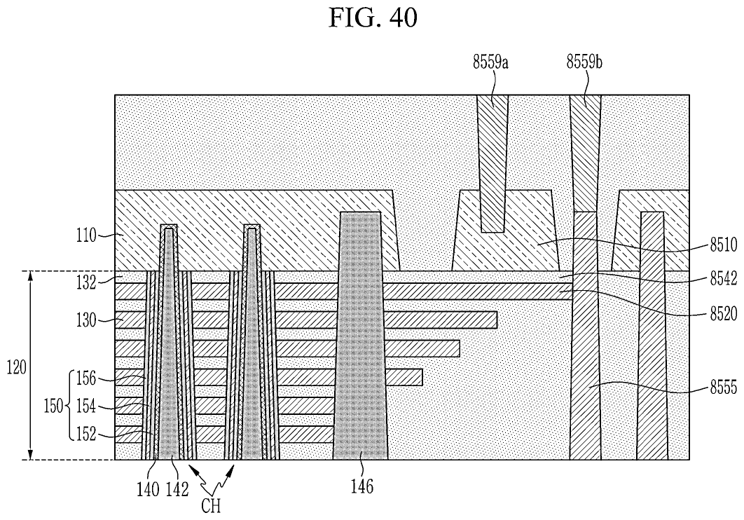

A semiconductor device according to an example embodiment will now be described with reference to FIG. 40.

FIG. 40 shows a cross-sectional view of a region of a semiconductor device according to an example embodiment.

The example embodiment shown in FIG. 40 mostly corresponds to the example embodiment shown in FIG. 33 so the description thereof will be omitted and the differences will be mainly described. In addition, the same or similar reference numerals are used for constituent elements that are identical or similar to those of the previous example embodiment. The present example embodiment is partially different from the previous example embodiment in that the upper sides of the second substrate and the first capacitor electrode are planar, which will now be described.

As shown in FIG. 40, the semiconductor device may include a first capacitor electrode 8510, a second capacitor electrode 8520, and a first dielectric layer 8542 disposed therebetween. The first capacitor electrode 8510 and the second capacitor electrode 8520 may overlap each other with the first dielectric layer 8542 therebetween to configure the first capacitor.

In the previous example embodiment, the upper sides of the second substrate 110 and the first capacitor electrode 8510 may not be planar. For example, a portion of the second substrate 110 for covering the channel structure CH and the separation structure 146 may be disposed higher than another portion of the second substrate 110 and the first capacitor electrode 8510.

In the present example embodiment, the upper sides of the second substrate 110 and the first capacitor electrode 8510 may be planar. A height of the upper side of the second substrate 110 may be substantially similar to a height of the upper side of the first capacitor electrode 8510. This difference may be generated according to various process conditions. For example, the second substrate 110 and the first capacitor electrode 8510 may be formed by using polysilicon in the previous example embodiment, and the second substrate 110 and the first capacitor electrode 8510 may be formed by using a metallic material in the present example embodiment.

An electronic system including a semiconductor device according to an example embodiment will now be described with reference to FIG. 41.

FIG. 41 shows an electronic system including a semiconductor device according to an example embodiment.

As shown in FIG. 41, the electronic system 1000 may include a semiconductor device 1100 and a controller 1200 electrically connected to the semiconductor device 1100. The electronic system 1000 may be a storage device including one or multiple semiconductor devices 1100 or an electronic device including the storage device. For example, the electronic system 1000 may be a solid state drive (SSD) device including one or multiple semiconductor devices 1100, a universal serial bus (USB), a computing system, a medical device, or a communication device.

The semiconductor device 1100 may be a non-volatile memory device, for example, a NAND flash memory device described with reference to FIG. 1 to FIG. 3. However, without being limited thereto, the semiconductor device 1100 may be a NAND flash memory device according to other modifiable example embodiments. The semiconductor device 1100 may include a first structure 1100F and a second structure 1100S disposed on the first structure 1100F. In an example embodiment, the first structure 1100F may be disposed near the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

Regarding the second structure 1100S, the respective memory cell strings CSTR may include lower transistors LT1 and LT2 disposed near the common source line CSL, upper transistors UT1 and UT2 disposed near the bit line BL, and memory cell transistors MCT disposed between the lower transistors LT1 and LT2 and the upper transistors UT1 and UT2. The number of the lower transistors LT1 and LT2 and the number of the upper transistors UT1 and UT2 may be modifiable in many ways depending on example embodiments.

In an example embodiment, the lower transistors LT1 and LT2 may include a ground selecting transistor, and the upper transistors UT1 and UT2 may include a string selecting transistor. The first and second gate lower lines LL1 and LL2 may be gate electrodes of the lower transistors LT1 and LT2. The word line WL may be a gate electrode of the memory cell transistor MCT, and the gate upper lines UL1 and UL2 may be gate electrodes of the upper transistors UT1 and UT2.

The common source line CSL, the first and second gate lower lines LL1 and LL2, the word line WL, and the first and second gate upper lines UL1 and UL2 may be electrically connected to the decoder circuit 1110 through the first connecting wire 1115 extending to the second structure 1100S in the first structure 1100F. The bit line BL may be electrically connected to the page buffer 1120 through the second connecting wire 1125 extending to the second structure 1100S in the first structure 1100F.

Regarding the first structure 1100F, the decoder circuit 1110 and the page buffer 1120 may control at least one of the memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connecting wire 1135 extending to the second structure 1100S in the first structure 1100F.

The controller 1200 may include a processor 1210, a NAND controller 1220, and a host interface 1230. Depending on example embodiments, the electronic system 1000 may include semiconductor devices 1100, and the controller 1200 may control the semiconductor devices 1100.

The processor 1210 may control general operation of the electronic system 1000 including the controller 1200. The processor 1210 may be operable according to predetermined firmware, and may control the NAND controller 1220 to access the semiconductor device 1100. The NAND controller 1220 may include a NAND interface 1221 for processing communication with the semiconductor device 1100. Control instructions for controlling the semiconductor device 1100, data to be written to the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When receiving the control instruction from the external host through the host interface 1230, the processor 1210 may control the semiconductor device 1100 in response to the control instruction.

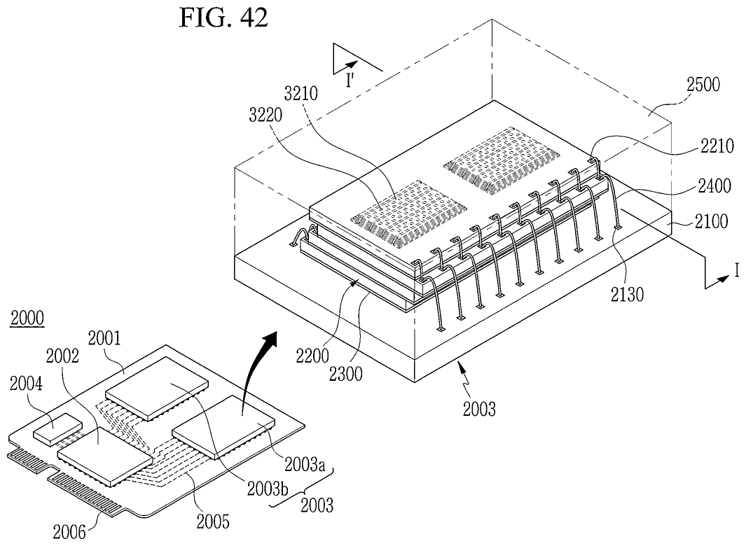

FIG. 42 shows a perspective view of an electronic system including a semiconductor device according to an example embodiment.

As shown in FIG. 42, the electronic system 2000 may include a main substrate 2001, a controller 2002 installed on the main substrate 2001, at least one semiconductor package 2003, and a DRAM 2004. The semiconductor package 2003 and the DRAM 2004 may be connected to the controller 2002 by a wire pattern 2005 formed on the main substrate 2001.

The main substrate 2001 may include a connector 2006 including pins combined to the external host. The number and the disposition of the pins of the connector 2006 are variable by a communication interface between the electronic system 2000 and the external host. In an example embodiment, the electronic system 2000 may communicate with the external host according to one of the interfaces including a universal serial bus (USB), a peripheral component interconnect express (PCI-Express), a serial advanced technology attachment (SATA), and a universal flash storage (UFS) M-Phy. In an example embodiment, the electronic system 2000 may be operated by a power voltage supplied by the external host through the connector 2006. The electronic system 2000 may further include a power management integrated circuit (PMIC) for providing the power voltage supplied by the external host to the controller 2002 and the semiconductor package 2003.

The controller 2002 may write data to the semiconductor package 2003, may read the data from the semiconductor package 2003, and may increase operation rates of the electronic system 2000.

The DRAM 2004 may be a buffer memory for reducing rate differences between the semiconductor package 2003 that is a data storage space and the external host. The DRAM 2004 included in the electronic system 2000 may be operated as a cache memory, and may provide a space for temporarily storing data when controlling the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced from each other. The first and second semiconductor packages 2003a and 2003b may respectively include semiconductor chips 2200. The first and second semiconductor packages 2003a and 2003b may include a package substrate 2100, semiconductor chips 2200 disposed on the package substrate 2100, an adhesive layer 2300 disposed on bottom surfaces of the respective semiconductor chips 2200, a connection structure 2400 for electrically connecting the semiconductor chips 2200 and the package substrate 2100, and a molding layer 2500 for covering the semiconductor chips 2200 and the connection structure 2400 on the package substrate 2100.

The package substrate 2100 may be a printed circuit board including a package upper pad 2130. The respective semiconductor chips 2200 may include an input/output pad 2210. The input/output pad 2210 may correspond to the input and output pad 1101 of FIG. 41. The respective semiconductor chips 2200 may include a gate stacking structure 3210 and a channel structure 322. The respective semiconductor chips 2200 may include the semiconductor device described with reference to FIG. 1 to FIG. 3. However, it is not limited to this, and the semiconductor chips 2200 may include a semiconductor device according to another modified example embodiment.

In an example embodiment, the connection structure 2400 may be a bonding wire for electrically connecting the input/output pad 2210 and the package upper pad 2130. Therefore, regarding the first and second semiconductor packages 2003a and 2003b, the semiconductor chips 2200 may be electrically connected to each other by a wire bonding method, and may be electrically connected to the package upper pad 2130 of the package substrate 2100. Depending on example embodiments, regarding the first and second semiconductor packages 2003a and 2003b, the semiconductor chips 2200 may be electrically connected to each other not by the connection structure 2400 according to a wire bonding method but by a connection structure including a through silicon via TSV.

In an example embodiment, the controller 2002 and the semiconductor chips 2200 may be included in one package. For example, the controller 2002 and the semiconductor chips 2200 may be installed on an interposer substrate that is different from the main substrate 2001, and the controller 2002 may be connected to the semiconductor chips 2200 by a wire formed on the interposer substrate.

FIG. 43 and FIG. 44 show cross-sectional views of a semiconductor package according to an example embodiment. FIG. 43 and FIG. 44 respectively show an example embodiment of the semiconductor package 2003 of FIG. 42, and conceptually show an incised region of the semiconductor package 2003 of FIG. 42 along a cutting line I-I′.

Referring to FIG. 43, regarding the semiconductor package 2003, the package substrate 2100 may be a printed circuit board. The package substrate 2100 may include a package substrate body portion 2120, a package upper pad 2130 disposed on an upper side of the package substrate body portion 2120, a lower pad 2125 disposed on a lower side of the package substrate body portion 2120 or exposed through the lower side, and an internal wire 2135 for electrically connecting the upper pad 2130 and the lower pad 2125 inside the package substrate body portion 2120. The upper pad 2130 may be electrically connected to the connection structure 2400. The lower pad 2125 may be connected to the wire pattern 2005 of the main substrate 2001 of the electronic system 2000 through a conductive connector 2800 as shown in FIG. 42.

The semiconductor chips 2200 may include a semiconductor substrate 3010 and a first structure 3100 and a second structure 3200 sequentially stacked on the semiconductor substrate 3010. The first structure 3100 may include a peripheral circuit region including a peripheral wire 3110. The second structure 3200 may include a common source line 3205, a gate stacking structure 3210 disposed on the common source line 3205, a channel structure 3220 and a separation structure 3230 passing through the gate stacking structure 3210, a bit line 3240 electrically connected to the channel structure 3220, and a gate connecting wire electrically connected to the word line WL of FIG. 41 of the gate stacking structure 3210.

Regarding the semiconductor chip 2200 or the semiconductor device according to an example embodiment, the respective electrodes configuring the capacitor disposed in the capacitor region, and dielectric layers disposed among them, and voltage lines connected to the respective electrodes may be disposed on the same layer as constituent elements disposed in the circuit region and the cell region. That is, the process may be simplified and the integration may be increased by forming the capacitor in the capacitor region by using the constituent elements disposed in the circuit region and the cell region.

The respective semiconductor chips 2200 may include a penetrating wire 3245 electrically connected to the peripheral wire 3110 of the first structure 3100 and extending into the second structure 3200. The penetrating wire 3245 may pass through the gate stacking structure 3210, and may be further disposed on the outside of the gate stacking structure 3210. The respective semiconductor chips 2200 may further include an input/output connecting wire 3265 electrically connected to the peripheral wire 3110 of the first structure 3100 and extending into the second structure 3200 and an input/output pad 2210 electrically connected to the input/output connecting wire 3265.

In an example embodiment, the semiconductor chips 2200 may be electrically connected to each other by the connection structure 2400 in a bonding wire form in the semiconductor package 2003. For another example, the semiconductor chips 2200 or portions configuring them may be electrically connected to each other by a connection structure including a through silicon via TSV.

Referring to FIG. 44, regarding the semiconductor package 2003A, the respective semiconductor chips 2200 may include a semiconductor substrate 4010, a first structure 4100 disposed on the semiconductor substrate 4010, and a second structure 4200 bonded to the first structure 4100 on the first structure 4100 by a wafer bonding method.

The first structure 4100 may include a peripheral circuit region including a peripheral wire 4110 and a first junction structure 4150. The second structure 4200 may include a common source line 4205, a gate stacking structure 4210 disposed between the common source line 4205 and the first structure 4100, a channel structure 4220 and a separation structure 4230 passing through the gate stacking structure 4210, and a second junction structure 4250 electrically connected to the word line WL of FIG. 22 of the channel structure 4220 and the gate stacking structure 4210. For example, the second junction structure 4250 may be electrically connected to the channel structure 4220 and the word line WL through the bit line 4240 electrically connected to the channel structure 4220 and the gate connecting wire electrically connected to the word line WL. The first junction structure 4150 of the first structure 4100 and the second junction structure 4250 of the second structure 4200 may contact each other and may be bonded to each other. The bonded portion of the first junction structure 4150 and the second junction structure 4250 may be made of, for example, copper (Cu).

Regarding the semiconductor chip 2200 or the semiconductor device according to an example embodiment, the respective electrodes configuring the capacitor disposed in the capacitor region, and dielectric layers disposed among them, and voltage lines connected to the respective electrodes may be disposed on the same layer as constituent elements disposed in the circuit region and the cell region. That is, the process may be simplified and the integration may be increased by forming the capacitor in the capacitor region by using the constituent elements disposed in the circuit region and the cell region.

The respective semiconductor chips 2200 may further include an input/output pad 2210 and an input and output connecting wire 4265 disposed on a lower portion of the input/output pad 2210. The input/output connecting wire 4265 may be electrically connected to a portion of the second junction structure 4250.

In an example embodiment, the semiconductor chips 2200 may be electrically connected to each other by the connection structure 2400 in a bonding wire shape in the semiconductor package 2003. For another example, the semiconductor chips 2200 or portions configuring the same may be electrically connected to each other by a connection structure including through silicon vias.

Throughout the specification and claims, when a part is “connected” to another part, it includes not only a case where the part is “directly connected” but also the case where the parts are “indirectly connected” with another part in between.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a first substrate;
a wiring layer on the first substrate;
a second substrate on the wiring layer and including a conductive material;
a first horizontal conductive layer and a second horizontal conductive layer sequentially stacked on the second substrate and connected to the second substrate;
a gate stacking structure including an interlayer insulating layer and a gate electrode alternately stacked on the second horizontal conductive layer;
a channel structure passing through the gate stacking structure and connected to the second substrate;
a first capacitor electrode on a same layer as the second substrate;
a second capacitor electrode overlapping the first capacitor electrode; and
a first dielectric layer between the first capacitor electrode and the second capacitor electrode,
wherein the second capacitor electrode is on a same layer as at least one of the wiring layer, the second substrate, the first horizontal conductive layer, or the gate electrode.

2. The semiconductor device of claim 1, wherein
the second capacitor electrode is on a same layer as a portion of the first horizontal conductive layer, and
the first dielectric layer is on a same layer as another portion of the first horizontal conductive layer.

3. The semiconductor device of claim 2, further comprising:
a third capacitor electrode overlapping the second capacitor electrode, and
a second dielectric layer between the second capacitor electrode and the third capacitor electrode,
wherein the third capacitor electrode is on a same layer as the second horizontal conductive layer.

4. The semiconductor device of claim 3, further comprising:
a first voltage line connected to the first capacitor electrode,
a second voltage line connected to the second capacitor electrode, and
a first connection structure connecting the second capacitor electrode and the second voltage line and extending in a same direction as the channel structure.

5. The semiconductor device of claim 4, wherein
the first voltage line is on a same layer as the wiring layer, and
the first capacitor electrode is connected to the third capacitor electrode.

6. The semiconductor device of claim 4, further comprising:
a third voltage line connected to the third capacitor electrode,
wherein the third voltage line is on a same layer as the wiring layer.

7. The semiconductor device of claim 4, further comprising:
a second connection structure connected to the first capacitor electrode and extending in parallel to the channel structure, and
a third connection structure connected to the third capacitor electrode and extending in parallel to the channel structure.

8. The semiconductor device of claim 1, wherein
the second capacitor electrode is on a same layer as the wiring layer, and
the first dielectric layer is on a same layer as an insulation layer between the wiring layer and the second substrate.

9. The semiconductor device of claim 8, further comprising:
a first voltage line connected to the first capacitor electrode,
wherein the first voltage line is on a same layer as the wiring layer.

10. The semiconductor device of claim 1, wherein
the second capacitor electrode on a same layer as the second substrate, and
a sum of a thickness of the first capacitor electrode and a thickness of the second capacitor electrode corresponds to a thickness of the second substrate.

11. The semiconductor device of claim 10, further comprising:
a first voltage line connected to the first capacitor electrode, and
a second voltage line connected to the second capacitor electrode,
wherein the first voltage line and the second voltage line are on a same layer as the wiring layer.

12. The semiconductor device of claim 11, further comprising:
a first barrier layer between the first capacitor electrode and the first voltage line, and
a second barrier layer between the second capacitor electrode and the second voltage line.

13. The semiconductor device of claim 12, further comprising:
a floating electrode connected to the second substrate,
a first dummy barrier layer on a same layer as the first barrier layer, and
a second dummy barrier layer on a same layer as the second barrier layer,
wherein the floating electrode is on a same layer as the wiring layer,
the first dummy barrier layer is between the floating electrode and the second substrate,
the second substrate includes a first layer and a second layer on the first layer, and
the second dummy barrier layer is between the first layer and the second layer.

14. The semiconductor device of claim 1, wherein
the second capacitor electrode is on a same layer as the gate electrode,
the first dielectric layer is on a same layer as the interlayer insulating layer, and
a portion of the first capacitor electrode is on a same layer as the first horizontal conductive layer.

15. The semiconductor device of claim 14, further comprising:
a first voltage line connected to the first capacitor electrode,
a second voltage line connected to the second capacitor electrode, and
a connection structure connecting the second capacitor electrode and the second voltage line and extending in a same direction as the channel structure,
wherein the first voltage line and the second voltage line are on a same layer as the wiring layer.

16. A semiconductor device comprising:
a first substrate;
a second substrate to face the first substrate and including a conductive material;
a wiring layer between the first substrate and the second substrate;
a gate stacking structure including an interlayer insulating layer and a gate electrode alternately stacked between the wiring layer and the second substrate;
a channel structure passing through the gate stacking structure and connected to the second substrate;
a first capacitor electrode on a same layer as the second substrate;
a second capacitor electrode overlapping the first capacitor electrode; and
a first dielectric layer between the first capacitor electrode and the second capacitor electrode,
wherein the second capacitor electrode is same layer as at least one of the wiring layer, the second substrate, or the gate electrode.

17. The semiconductor device of claim 16, wherein
the first capacitor electrode is separated from the second substrate.

18. The semiconductor device of claim 16, further comprising:
a first connection electrode connected to the first capacitor electrode.

19. An electronic system comprising:
a main substrate;
a semiconductor device on the main substrate; and
a controller electrically connected to the semiconductor device on the main substrate,
wherein the semiconductor device includes
a first substrate,
a wiring layer on the first substrate,
a second substrate on the wiring layer and including a conductive material, a gate stacking structure including an interlayer insulating layer and a gate electrode alternately stacked on the second substrate,
a channel structure passing through the gate stacking structure and connected to the second substrate,
a first capacitor electrode on a same layer as the second substrate,
a second capacitor electrode overlapping the first capacitor electrode, and
a first dielectric layer between the first capacitor electrode and the second capacitor electrode,
wherein the second capacitor electrode is on a same layer as at least one of the wiring layer, the second substrate, or the gate electrode.

20. The electronic system of claim 19, wherein
the second capacitor electrode is on a same layer as the wiring layer, and
the first dielectric layer is on a same layer as an insulation layer between the wiring layer and the second substrate.
